(19) United States
(12) Patent Application Publication
(10) Pub. No.: US 2021/0050547 A1
(43) Pub. Date: Feb. 18, 2021

(54) ELECTROLUMINESCENT DEVICE BASED ON BORON-CONTAINING ORGANIC COMPOUND

(71) Applicant: JIANGSU SUNERA TECHNOLOGY CO., LTD., Wuxi (CN)

(72) Inventors: CHONG LI, WUXI (CN); ZHONGHUA YE, WUXI (CN); ZHAOCHAO ZHANG, WUXI (CN)

(21) Appl. No.: 17/086,426

(22) Filed: Nov. 1, 2020

Related U.S. Application Data
(63) Continuation of application No. PCT/CN2019/086679, filed on May 13, 2019.

(30) Foreign Application Priority Data
May 14, 2018 (CN) 201810455724.3

(51) Int. Cl. H01L 51/50; H01L 51/00

(52) U.S. Cl. CPC H01L 51/5024; H01L 51/008; H01L 51/0072; H01L 2251/552; H01L 51/5092; H01L 51/5072; H01L 51/5056; H01L 51/5004

(57) ABSTRACT

The disclosure relates to an organic electroluminescent device with an exciplex as a host material, particularly to an organic electroluminescent device comprising a host material and a fluorescent material. The host material comprises a first organic compound and a second organic compound; a mixture or interface formed by the first organic compound and the second organic compound generates the exciplex under the condition of optical excitation or electric field excitation; the emission spectrum of the formed exciplex and the absorption spectrum of the fluorescent doping material have effective overlapping to form effective energy transfer; furthermore, the first organic compound and the second organic compound have different carrier transport characteristics; wherein the fluorescent material is an organic compound containing boron atoms. The organic electroluminescent device prepared by the method has the characteristics of high efficiency and long lifetime.

### CROSS-REFERENCE TO RELATED APPLICATIONS

This application is a continuation of International Patent Application No. PCT/CN2019/086679 with a filing date of May 13, 2019, designating the United States, now pending, and further claims priority to Chinese Patent Application No. 201810455724.3 with a filing date of May 14, 2018. The content of the aforementioned applications, including any intervening amendments thereto, are incorporated herein by reference.

### TECHNICAL FIELD

The disclosure relates to the technical field of semiconductors, and particularly to an organic electroluminescent device having high color purity, high efficiency and long lifetime.

### BACKGROUND

The organic light emitting diode (OLED) has been positively researched and developed. The simplest basic structure of an organic electroluminescent device includes a luminescent layer which is sandwiched between a negative electrode and a positive electrode. The organic electroluminescent device is considered as a next-generation panel display material so as to attract much attention because it can realize ultra-thin ultra-lightweight, fast input signal response speed and low-voltage DC drive.

It is believed that the organic electroluminescent device has the following luminescence mechanism: when a voltage is applied between electrodes sandwiched with the luminescent layer, holes injected from the positive electrode and electrons injected from the negative electrode are recombined in the luminescent layer to form excitons, and the excitons are relaxed to a ground state to release energy to form photons. In the organic electroluminescent device, the luminescent layer usually requires that a fluorescent material is doped in a host material to obtain more efficient energy transfer efficiency and give full play to the luminous potential of the fluorescent material. In order to obtain high host fluorescent energy transfer efficiency, the matching of host fluorescent materials and the balance degree of electrons and holes inside the host material are key factors to obtain high-efficiency devices. The carrier mobility of electrons and holes inside the existing host material often has significant difference, which leads to a fact that the exciton recombination area deviates from the luminescent layer to result in low efficiency and poor stability of the existing device.

The application of organic light-emitting diodes (OLEDs) in the aspects of large area panel display and illumination has attracted wide attention from industry and academia. However, the traditional organic fluorescent material can only utilize 25% singlet excitons formed by electrical excitation to emit light, and the internal quantum efficiency of the device is low (up to 25%). The external quantum efficiency is generally less than 5%, which is far from the efficiency of a phosphorescent device. Although the phosphorescent material can emit light by effectively utilizing singlet excitons and triplet excitons so that the internal quantum efficiency of the device is up to 100% because of strong spin-orbit coupling intersystem in the center of heavy atoms, the phosphorescent material can effectively utilize the singlet and triplet excitons formed by electric excitation to emit light, and the internal quantum efficiency of the devices can reach 100%. However, the phosphorescent material has some problems of expensive price, poor material stability and serious device efficiency drop so as to limit its application in OLEDs.

The thermally activated delayed fluorescence (TADF) material is a third-generation organic luminescent material after the organic fluorescent material and the organic phosphorescent material. The material generally has a small singlet and triplet energy level difference (REST), and triplet excitons can be converted into singlet excitons through the inverse intersystem crossing to emit light. This can make full use of the singlet and triplet excitons formed under the electric excitation, and the internal quantum efficiency of the device can reach 100%. At the same time, the material has controllable structure, stable property, low price and no precious metals, and has a broad application prospect in the field of OLEDs.

Although the TADF material can achieve 100% of exciton utilization rate in theory, actually, there are some problems: (1) the T1 and S1 states of the molecule are designed to have strong CT characteristics and a very small S1-T1 state energy gap. Although the transition rate of excitons in the T1→S1 state can be achieved through TADF process, low S1 state radiation transition rate is simultaneously caused, thus it is difficult to simultaneously consider (or simultaneously realize) high exciton utilization rate and high fluorescent radiation efficiency;

(2) Because TADF materials with D-A, D-A-D or A-D-A structures are used at present, the configurations of the molecule change greatly in the ground and excited states due to its large molecular flexibility, and the full width at half maximum (FWHM) of the spectrum of the material is too large so as to lead to the reduced color purity of the material;

(3) Even if doping devices have been used to reduce the quenching effect of T-exciton concentration, most devices made of the TADF materials have a serious efficiency drop at high current density. The devices have a serious efficiency drop at high current density.

(4) Due to different electron and hole transport rates of the host material, the traditional host fluorescence matching manner leads to reduction of the carrier recombination rate and decrease of device efficiency; at the same time, the carrier recombination area is close to one side of the host material side so that the carrier recombination area is too concentrated, resulting in the concentration of triplet exciton density, obvious carrier quenching phenomenon and reduced device efficiency and lifetime. In order to improve the efficiency and stability of the organic electroluminescent device, it is necessary to improve the device structure and develop the materials, so as to meet the needs of panel enterprises and lighting enterprises in the future.

### SUMMARY

In view of this, aiming at the above problems in the prior art, the disclosure provides an organic electroluminescent device. The device of the disclosure, on the one hand, can effectively balance the carriers inside the device and reduce the quenching effect of the excitons, and on the other hand, can effectively reduce the FWHM of the spectrum and effectively improve the efficiency, lifetime and color purity of the organic light-emitting device.

The technical solution of the disclosure is as follows: the present application provides an organic electroluminescent device, comprising a negative electrode, a positive electrode and a luminescent layer located between the negative electrode and the positive electrode; the luminescent layer comprising a host material and a fluorescent material; a hole transport area being present between the positive electrode and the luminescent layer, and an electron transport area being present between the negative electrode and the luminescent layer; wherein,

the host material comprises a first organic compound and a second organic compound, a mixture or interface formed by the first organic compound and the second organic compound generates an exciplex under the condition of optical excitation or electric field excitation; the emission spectrum of the formed exciplex and the absorption spectrum of the fluorescent doping material are effectively overlapped at the longest wavelength, and the first organic compound and the second organic compound have different carrier transport characteristics;

the fluorescent material is doped into the host material, the fluorescent material is an organic compound containing boron atoms, and the longest wavelength side of the absorption spectrum of the fluorescent material and the emission spectrum of the exciplex are overlapped.

Preferably, the first organic compound and the second organic compound form a mixture in a mass ratio of 1:99˜99:1 to generate the exciplex under the condition of optical excitation or electric field excitation.

Preferably, the first organic compound and the second organic compound form an overlapping layer of an interface, the first organic compound is located at one side of a hole transport area, the second organic compound is located at one side of the electron transport area, and the exciplex is generated under the condition of optical excitation or electric field excitation.

Preferably, the host material in the luminescent layer is the mixture formed by the first organic compound and the second organic compound, wherein the first organic compound is 10%˜90% by mass of the host material; the fluorescent material in the luminescent layer is 1%˜5% or 5%˜30% by mass of the host material.

Preferably, the host material in the luminescent layer is the overlapping layer of the interface formed by the first organic compound and the second organic compound; the fluorescent material is doped into the first organic compound, and the fluorescent material in the luminescent layer is 1%˜5% by mass of the host material; or the fluorescent material is doped into the second organic compound, and the fluorescent material in the luminescent layer is 1%˜5% by mass of the host material.

Preferably, the host material in the luminescent layer is the overlapping layer of the interface formed by the first organic compound and the second organic compound; the fluorescent material is doped into the first organic compound, and the fluorescent material in the luminescent layer is 5%˜30% by mass of the host material; or the fluorescent material is doped into the second organic compound, and the fluorescent material in the luminescent layer is 5%˜30% by mass of the host material.

Preferably, the hole mobility of the first organic compound is greater than an electron mobility, and the electron mobility of the second organic compound is greater than the hole mobility; and the first organic compound is a hole transfer type material, and the second organic compound is an electron transfer type material.

Preferably, a difference between the highest peak wavelength of the fluorescence emission spectrum of the exciplex and the highest energy peak wavelength of the phosphorescence emission spectrum of the exciplex is less than or equal to 50 nm; the energy is transferred to a fluorescent boron-containing doping material, so that the fluorescent boron-containing material emits light.

Preferably, the wavelength of the luminescent peak of the fluorescent material is 400˜500 nm or 500˜560 nm or 560˜780 nm.

Preferably, a difference between the highest peak wavelength of the fluorescence emission spectrum of the fluorescent material and the highest peak wavelength of the phosphorescence emission spectrum of the fluorescent material is less than or equal to 50 nm.

Preferably, the quantity of boron atoms contained in the fluorescent material is greater than or equal to 1, boron atoms are bonded with other elements through sp2 hybrid orbits; a group connected with boron is one of a hydrogen atom, substituted or unsubstituted C1-C6 linear alkyl, substituted or unsubstituted C3-C10 cycloalkyl, substituted or unsubstituted C1-C10 heterocycloalkyl, substituted or unsubstituted C6-C60 aryl, substituted or unsubstituted C3-C60 heteroaryl; furthermore, the groups connected with boron can be connected alone, or mutually and directly bonded to form a ring, or connected with boron after being connected with other groups to form the ring. Preferably, the quantity of boron atoms contained in the fluorescent material is 1, 2 or 3.

Preferably, the guest material has a structure as shown in general formula (1):

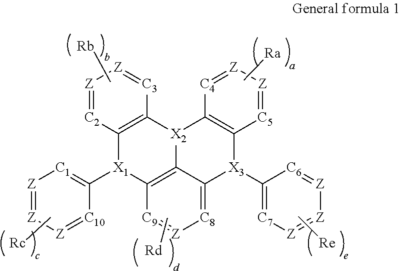

wherein, X₁, X₂ and X₃ each independently represent a nitrogen atom or a boron atom, and at least one of X₁, X₂ and X₃ is the boron atom; Z, on each occurrence, identically or differently represents N or C(R);

a, b, c, d and e each independently represent 0, 1, 2, 3, or 4;

at least one pair of C₁ and C₂, C₃ and C₄, C₅ and C₆, C₇ and C₈, C₉ and C₁₀ can be connected to form a 5-7-membered ring structure;

R, on each occurrence, identically or differently represents H, D, F, Cl, Br, I, C(═O)R¹, CN, Si(R¹)₃, P(═O)(R¹)₂, S(═O)₂R¹, linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups of the groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, or SO₂, and wherein one or more H atoms in the groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;

R¹, on each occurrence, identically or differently represents H, D, F, Cl, Br, I, C(═O)R², CN, Si(R²)₃, P(═O)(R²)₂, N(R²)S(═O)₂R², linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R₂C═CR2-, —C≡C—, Si(R²)₂, C(═O), C═NR², —C(═O)O—, C(═O)NR²—, NR², P(═O)(R²), —O—, —S—, or SO₂, and one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;

R², on each occurrence, identically or differently represents H, D, F or C1-C20 aliphatic, aromatic or heteroaromatic organic groups, and one or more H atoms can also be substituted by D or F; here, two or more substituents R² can be connected to each other and form a ring;

Ra, Rb, Rc and Rd each independently represent linear or branched C1-C20 alkyl groups, linear or branched C1-C20 alkyl substituted silyl, substituted or unsubstituted C5-C30 aryl, substituted or unsubstituted C5-C30 heteroaryl, and substituted or unsubstituted C5-C30 arylamino;

under the condition that the Ra, Rb, Rc and Rd groups are bonded with Z, the group Z is equal to C.

Preferably, the guest material has a structure as shown in general formula (2):

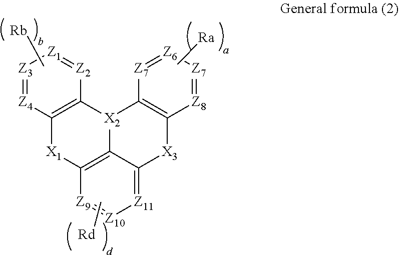

wherein, X₁ and X₃ each independently represent a single bond, B(R), N(R), C(R)₂, Si(R)₂, O, C═N(R), C═C(R)₂, P(R), P(═O)R, S or SO₂; X₂ independently represents a nitrogen atom or a boron atom, and at least one of X₁, X₂ and X₃ is the boron atom;

Z₁-Z₁₁ independently represent the nitrogen atom or C(R), respectively;

a, b, c, d and e each independently represent 0, 1, 2, 3, or 4;

R, on each occurrence, identically or differently represents H, D, F, Cl, Br, I, C(═O)R¹, CN, Si(R¹)₃, P(═O)(R¹)₂, S(═O)₂R¹, linear C1-C20 alkyl or alkoxy group, or branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, or SO₂, and wherein one or more H atoms in the groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;

R¹ identically or differently represents H, D, F, Cl, Br, I, C(═O)R², CN, Si(R²)₃, P(═O) (R²)₂, N(R²)S(═O)₂R², linear C₁-C₂₀ alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R₂C═CR2-, —C≡C—, Si(R²)₂, C(═O), C═NR², —C(═O)O—, C(═O)NR²—, NR², P(═O)(R²), —O—, —S—, or SO₂, and one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;

R², on each occurrence, identically or differently represents H, D, F or C1-C20 aliphatic, aromatic or heteroaromatic organic groups at each occurrence, and one or more H atoms can also be substituted by D or F; here, two or more substituents R² can be connected to each other and form a ring;

Ra, Rb, Rc and Rd each independently represent linear or branched C1-C20 alkyl groups, linear or branched C1-C20 alkyl substituted silyl, substituted or unsubstituted C5-C30 aryl, substituted or unsubstituted C5-C30 heteroaryl, and substituted or unsubstituted C5-C30 arylamino;

under the condition that the Ra, Rb, Rc and Rd groups are bonded with Z, the group Z is equal to C.

Preferably, the guest material has a structure as shown in general formula (3):

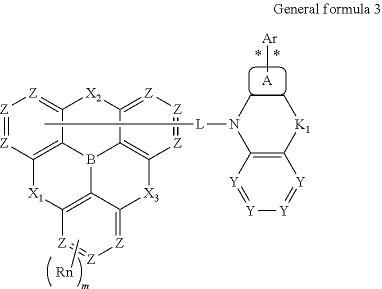

wherein, X₁, X₂ and X₃ each independently represent a single bond, B(R), N(R), C(R)₂, Si(R)₂, O, C═N(R), C═C(R)₂, P(R), P(═O)R, S or SO₂;

Z and Y at different positions independently represent C(R) or N, respectively;

K₁ represents one of a single bond, B(R), N(R), C(R)₂, Si(R)₂, O, C═NR), C═C(R)₂, P(R), P(═O)R, S or SO₂, linear or branched C1-C20 alkyl substituted alkylene, linear or branched C1-C20 alkyl substituted silyl and C6-C20 aryl substituted alkylene;

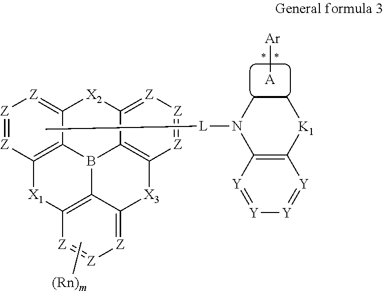

represents an aromatic group having carbon atom number of 6˜20 or a heteroaromatic group having carbon atom number of 3˜20;

m represents 0, 1, 2, 3, 4 or 5; L is selected from a single bond, a double bond, a triple bond, an aryl group having carbon atom number of 6˜40 or a heteroaromatic group having carbon atom number of 3˜40;

R, on each occurrence, identically or differently represents H, D, F, Cl, Br, I, C(═O)R¹, CN, Si(R¹)₃, P(═O)(R¹)₂, S(═O)₂R¹, linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, or SO₂, and wherein one or more H atoms in the groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;

R¹, on each occurrence, identically or differently represents H, D, F, Cl, Br, I, C(═O)R², CN, Si(R²)₃, P(═O) (R²)₂, N(R²)S(═O)₂R², linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R₂C═CR2-, —C≡C—, Si(R²)₂, C(═O), C═NR², —C(═O)O—, C(═O)NR²—, NR², P(═O)(R²), —O—, —S—, or SO₂, and one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;

R², on each occurrence, identically or differently represents H, D, F or C1-C20 aliphatic, aromatic or heteroaromatic organic groups, and one or more H atoms can also be substituted by D or F; here, two or more substituents R² can be connected to each other and form a ring;

Rₙ independently represents linear or branched C1-C20 alkyl substituted alkyl, linear or branched C1-C20 alkyl substituted silyl, substituted or unsubstituted C5-C30 aryl, substituted or unsubstituted C5-C30 heteroaryl, and substituted or unsubstituted C5-C30 arylamino;

Ar represents linear or branched C1-C20 alkyl substituted alkyl, linear or branched C1-C20 alkyl substituted silyl, substituted or unsubstituted C5-C30 aryl, substituted or unsubstituted C5-C30 heteroaryl, and substituted or unsubstituted C5-C30 arylamino or a structure shown in general formula (4):

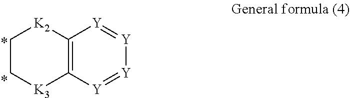

K₂ and K₃ independently represent one of a single bond, B(R), N(R), C(R)₂, Si(R)₂, O, C═N(R), C═C(R)₂, P(R), P(═O)R, S or SO₂, linear or branched C1-C20 alkyl substituted alkylene, linear or branched C1-C20 alkyl substituted silyl and C6-C20 aryl substituted alkylene, respectively;

* represents ligation sites of general formula (4) and general formula (3).

Preferably, in general formula (3), X₁, X₂ and X₃ each can also be independently absent, namely, none of atoms or bond linkages is each independently present at the positions represented by X₁, X₂ and X₃, and the atom or bond is present at the position of at least one of X₁, X₂ and X₃.

Preferably, the hole transport area comprises one or a combination of more of a hole injection layer, a hole transport layer and an electron barrier layer; the electron transport area comprises one or a combination of more of an electron injection layer, an electron transport layer and a hole barrier layer.

The present application also provides an illumination or display element, comprising one or more organic electroluminescent devices as described above; and under the condition that multiple devices are contained, the devices are horizontally or longitudinally overlapped and combined.

The disclosure has the beneficial effects:

The disclosure provides an organic electroluminescent device. The host material of the luminescent layer of the organic electroluminescent device is formed by matching two materials. The mixture or interface formed by the two materials can produce exciplexes under the condition of optical excitation and electric excitation, which can decrease the concentration of triplet excitons of the host material, reduce the quenching effect of triplet excitons, and improve the stability of the device. The second compound is a material with a carrier mobility different from that of the first compound, which can balance the carriers inside the host material, increase the exciton recombination area, and improve the efficiency of the device while effectively solving the color shift problem of the material under high current density, and improving the stability of the light-emitting color of the device. The formed exciplex can rapidly convert triplet excitons into singlet excitons, reduce the quenching effect of triplet excitons and improve the stability of the device.

Meanwhile, the emission spectrum of the formed exciplex is overlapped with the longest wavelength side of the absorption spectrum of the fluorescent material, which ensures the effectiveness of energy from exciplex recombination to fluorescence doping transfer. The fluorescent material containing boron atoms is bonded with other atoms through sp2 hybrid form of boron. In the formed structure, because boron is an electron deficient atom, it can form charge transfer state or reverse space resonance effect with an electron donating group or a weak electron withdrawing group, resulting in separation of HOMO and LUMO electron cloud orbits, and reduction of the singlet-triplet energy level difference of the material, thereby generating the delayed fluorescence phenomenon; at the same time, the material formed with the boron atoms as the core can not only obtain very small singlet-triplet energy level difference, but also can effectively reduce the delayed fluorescence lifetime of the material due to its fast fluorescence radiation rate, thus reducing the triplet quenching effect and improving the device efficiency. In addition, due to the existence of the boron atoms, the intra-molecular rigidity is enhanced, the molecular flexibility is reduced, the configuration difference between the ground state and the excited state of the material is reduced effectively, the FWHM of the light-emitting spectrum of the material is effectively reduced, and the promotion of the device is facilitated, thereby improving the color gamut of the device. Therefore, the device structure matching of the disclosure can effectively improve the efficiency, lifetime and color purity of the device.

### BRIEF DESCRIPTION OF THE DRAWINGS

FIG. 1 is a diagram of an embodiment of an organic electroluminescent device of the disclosure, wherein 1, a substrate layer; 2, positive electrode layer; 3, hole injection layer; 4, hole transport layer; 5, electron barrier layer; 6, luminescent layer; 7, hole barrier/electron transport layer; 8, electron injection layer; 9, negative electrode layer.

FIG. 2 shows optical excitation emission spectrums of H3 and H7, and optical and electric excitation emission spectrums of H3:H7=50:50 and H3/H7 interface.

FIG. 3 shows optical excitation emission spectrums of H1 and H2, and optical and electric excitation emission spectrums of H1:H2=50:50 and H1/H2 interface.

FIG. 4 shows optical excitation emission spectrums of H3 and H9, and optical and electric excitation emission spectrums of H3:H9=50:50 and H3:H9=50:50 interface (no exciplex is generated under optical excitation).

FIG. 5 is absorption spectrums of BD-1, BD-2, DG-1, DG-2, DG-3, DG-4 and DR-1

FIG. 6 is a diagram of a built-in electric field principle (1);

FIG. 7 is a diagram of a built-in electric field principle (2).

FIG. 8 is an angle dependence spectrum of a single film.

FIG. 9 shows service lives of organic electroluminescent devices prepared in embodiments when working at different temperatures.

### DESCRIPTION OF THE EMBODIMENTS

In the context of the disclosure, unless otherwise stated, HOMO means the highest occupied molecular orbit, and LUMO means the lowest unoccupied molecular orbit. In addition, “LUMO energy level difference value” involved in the specification means a difference of the absolute value of each energy value.

In the context of the disclosure, unless otherwise stated, the singlet (S1) energy level refers to the lowest excited energy level of the singlet state of the molecule, the triplet (T1) energy level refers to the lowest excited energy level of the triplet state of the molecule. In addition, the “triplet energy level difference value” and “singlet and triple energy level difference value” involved in the specification refer to a difference of the absolute value of each energy. In addition, the difference value between levels is expressed with an absolute value.

In the disclosure, selection of the first organic compound and the second organic compound constituting the host material has no specific limitation, as long as the HOMO and LUMO, singlet state and triplet state and carrier mobility can all meet the above conditions.

In a preferred embodiment, the first organic compound and the second organic compound constituting the host material are selected from H1, H2, H3, H4, H5, H6, H7, H8 and H9, but are not limited to the above materials, and their structures are as follows:

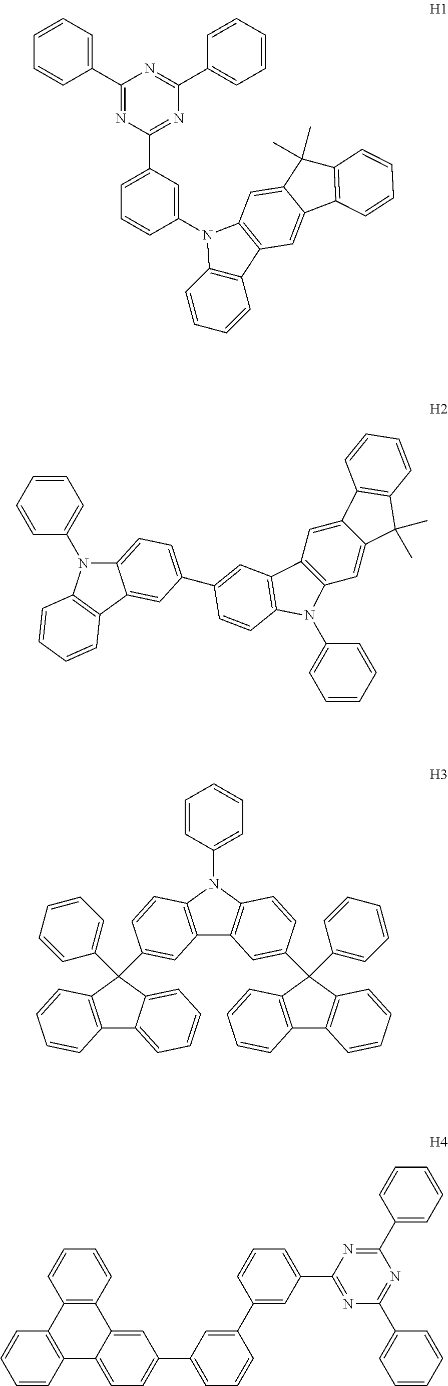 [SMILES: CC1(C)c2ccccc2-c2cc3c4ccccc4n(-c4cccc(-c5nc(-c6ccccc6)nc(-c6ccccc6)n5)c4)c3cc21 ; CC1(C)c2ccccc2-c2cc3c4cc(-c5ccc6c(c5)c5ccccc5n6-c5ccccc5)ccc4n(-c4ccccc4)c3cc21 ; c1ccc(-n2c3ccc(C4(c5ccccc5)c5ccccc5-c5ccccc54)cc3c3cc(C4(c5ccccc5)c5ccccc5-c5ccccc54)ccc32)cc1 ; c1ccc(-c2nc(-c3ccccc3)nc(-c3cccc(-c4cccc(-c5ccc6c7ccccc7c7ccccc7c6c5)c4)c3)n2)cc1]

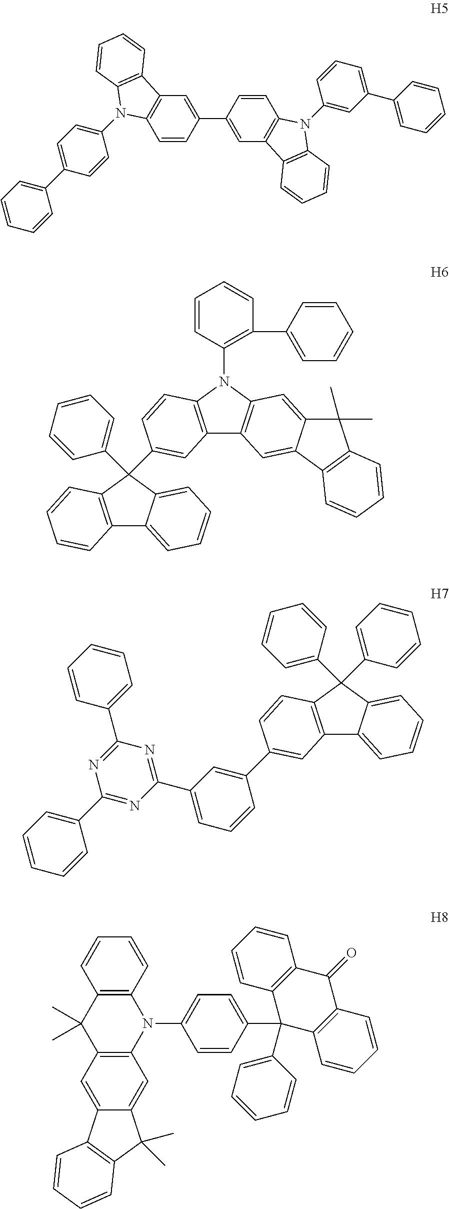 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; CC1(C)c2ccccc2-c2cc3c4cc(C5(c6ccccc6)c6ccccc6-c6ccccc65)ccc4n(-c4ccccc4-c4ccccc4)c3cc21 ; c1ccc(-c2nc(-c3ccccc3)nc(-c3cccc(-c4ccc5c(c4)-c4ccccc4C5(c4ccccc4)c4ccccc4)c3)n2)cc1 ; CC1(C)c2ccccc2-c2cc3c(cc21)N(c1ccc(C2(c4ccccc4)c4ccccc4C(=O)c4ccccc42)cc1)c1ccccc1C3(C)C]

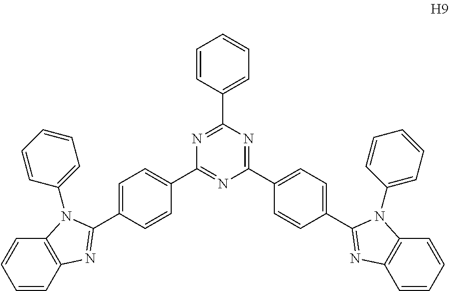 [SMILES: c1ccc(-c2nc(-c3ccc(-c4nc5ccccc5n4-c4ccccc4)cc3)nc(-c3ccc(-c4nc5ccccc5n4-c4ccccc4)cc3)n2)cc1]

The carrier mobilities of the above selected materials are as shown in Table 1:

TABLE 1

| Names of | Hole mobility | Electron mobility |
|---|---|---|
| materials | (cm²/V · S) | (cm²/V · S) |
| H1 | 2.01*10⁻⁴ | 1.56*10⁻² |
| H2 | 5.44*10⁻³ | 1.09*10⁻⁴ |
| H3 | 5.31*10⁻³ | 2.08*10⁻⁴ |
| H4 | 2.18*10⁻⁴ | 6.10*10⁻² |
| H5 | 8.76*10⁻³ | 1.24*10⁻⁴ |
| H6 | 7.12*10⁻³ | 2.35*10⁻⁴ |
| H7 | 3.12*10⁻⁴ | 4.52*10⁻³ |
| H8 | 4.11*10⁻⁴ | 1.01*10⁻² |
| H9 | 2.50*10⁻⁴ | 6.78*10⁻³ |

The energy levels of the above host materials and the energy levels of the formed exciplexes are as shown in Table 2:

TABLE 2

| Names of | HOMO | LUMO | PL Peak | EL Peak |
|---|---|---|---|---|
| materials | (eV) | (eV) | (nm) | (nm) |
| H1 | −5.82 | −2.80 | 477 | / |
| H2 | −5.60 | −2.17 | 414 | / |
| H3 | −6.01 | −2.58 | 383 | / |
| H4 | −6.23 | −2.64 | 310 | / |
| H5 | −5.64 | −2.27 | 414 | / |
| H6 | −5.78 | −2.50 | 394 | / |
| H7 | −6.48 | −2.89 | 380 | / |
| H8 | −5.57 | −2.25 | 547 | / |
| H9 | −6.52 | −3.43 | 444 | / |
| H1:H2 (50:50) | −5.60 | −2.80 | 510 | 512 |
| H1/H2 | −5.60 | −2.80 | 511 | 513 |
| H1/H3 | −5.60 | −2.80 | 508 | 509 |
| H4:H5 (50:50) | −5.64 | −2.64 | 481 | 483 |
| H4:H5 | −5.64 | −2.64 | 480 | 481 |
| H6:H7 (50:50) | −5.78 | −2.89 | 427 | 430 |
| H6/H7 | −5.78 | −2.89 | 428 | 429 |
| H3:H7 (50:50) | −6.01 | −2.89 | 402 | 404 |
| H3/H7 | −6.01 | −2.89 | 403 | 406 |
| H8:H3 (50:50) | −5.57 | −2.64 | / | 510 |
| H8/H3 | −5.57 | −2.64 | / | 512 |
| H9:H3 (50:50) | −6.01 | −3.43 | / | 520 |
| H9/H3 | −6.01 | −3.43 | / | 519 |

Note:
among them, H2:H3 (50:50) indicates that in the host material, the first organic compound and the second organic compound form a mixture having a mass ratio of 50:50; and H2/H3 indicates that in the host material, the first organic compound and the second organic compound form an interface. Wherein, PL represents the optical excitation spectrum and EL represents the electric field excitation spectrum.

It can be seen from the above table that the HOMO/LUMO energy level difference between the first organic compound and the second organic compound is greater than or equal to 0.2 eV, which indicates that the formation of the exciplex requires a certain energy level difference condition, and the first and second organic compounds that can not meet the condition form no exciplexes. If the mixture or interface formed by the first organic compound and the second organic compound can form the exciplex under optical excitation, it can also produce the exciplex under electric field excitation; if the exciplex cannot be produced under optical excitation, but exciplex is produced under electric field excitation, as long as the HOMO/LUMO energy level difference between the first organic compound and the second organic compound can meet requirements.

Particularly, in the host material of the luminescent layer, the first organic compound and the second organic compound form the mixture, wherein the first organic compound is 10%˜90% by mass of the host material. In a preferred embodiment, the mass ratio of the first organic compound to the host material can be 9:1˜1:9, preferably 8:2˜2:8, preferably 7:3˜3:7, more preferably 1:1; in the luminescent layer, the fluorescent material is 1%˜5% or 5%˜30% by mass of the host material.

Specifically, the fluorescent material of the organic electroluminescent device can be selected from the following compounds:

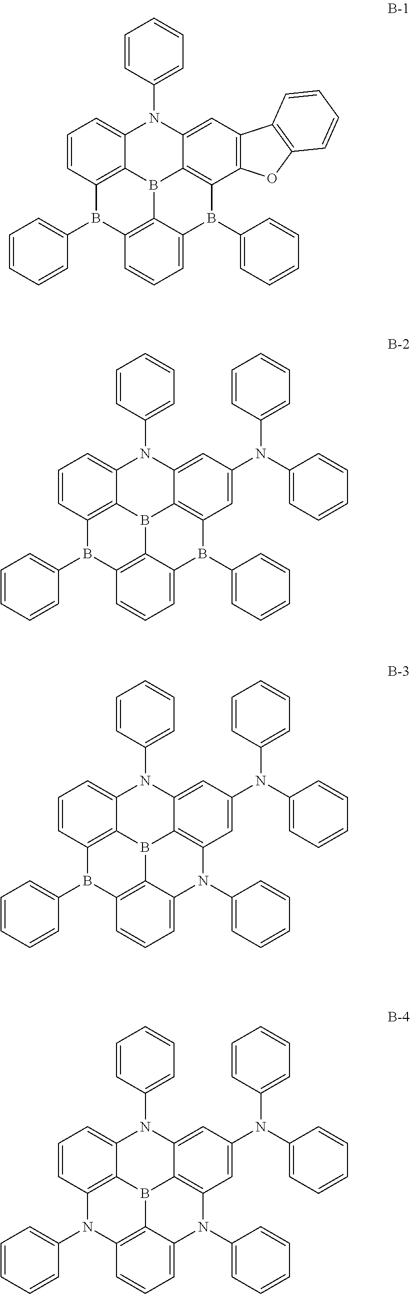 [SMILES: c1ccc(B2c3cccc4c3B3c5c2cccc5N(c2ccccc2)c2cc5c(oc6ccccc65)c(c23)B4c2ccccc2)cc1 ; c1ccc(B2c3cccc4c3B3c5c2cccc5N(c2ccccc2)c2cc(N(c5ccccc5)c5ccccc5)cc(c23)B4c2ccccc2)cc1 ; c1ccc(B2c3cccc4c3B3c5c2cccc5N(c2ccccc2)c2cc(N(c5ccccc5)c5ccccc5)cc(c23)N4c2ccccc2)cc1 ; c1ccc(N(c2ccccc2)c2cc3c4c(c2)N(c2ccccc2)c2cccc5c2B4c2c(cccc2N3c2ccccc2)N5c2ccccc2)cc1]

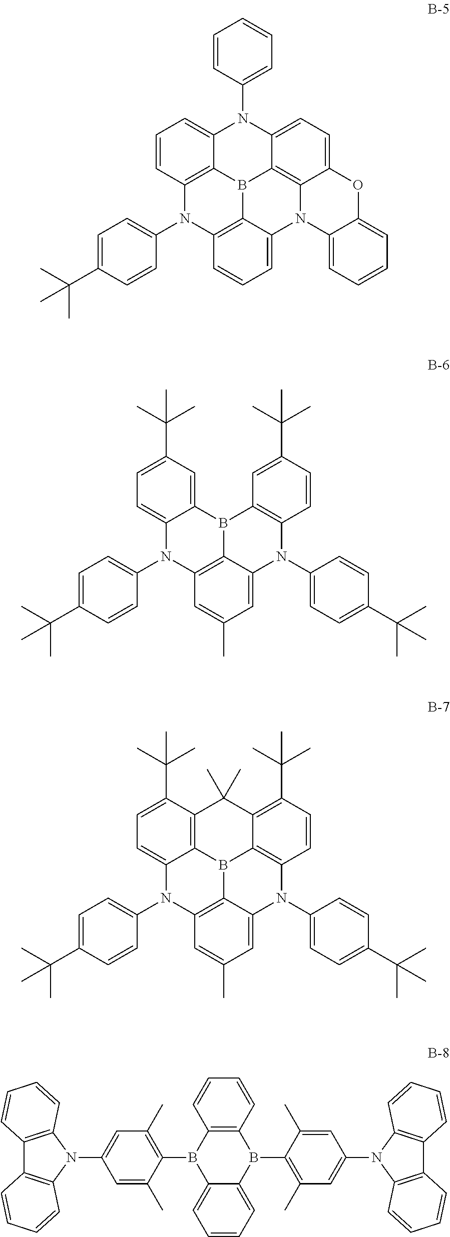

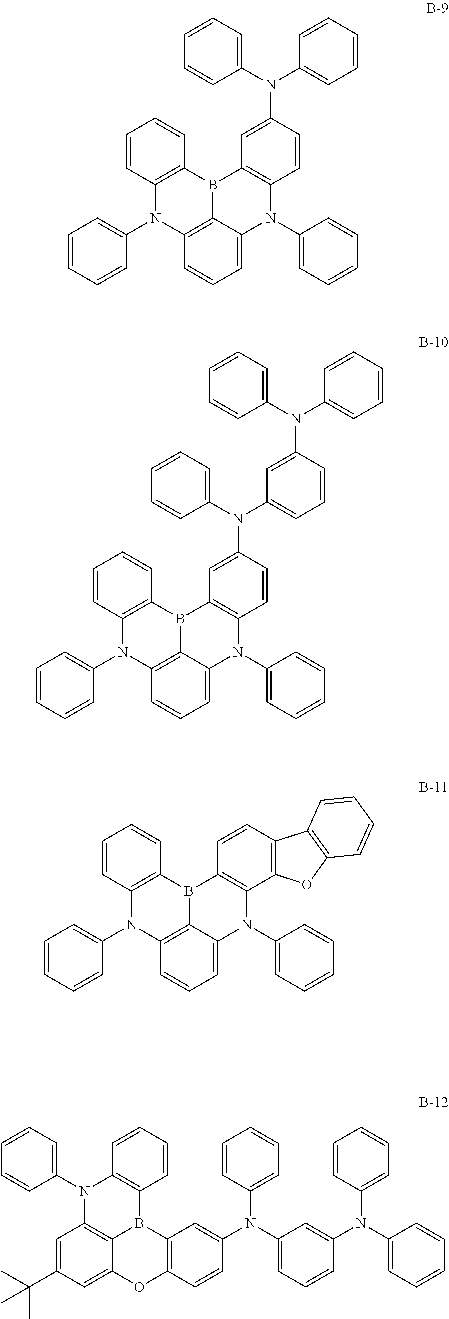 [SMILES: c1ccc(N(c2ccccc2)c2ccc3c(c2)B2c4ccccc4N(c4ccccc4)c4cccc(c42)N3c2ccccc2)cc1 ; c1ccc(N(c2ccccc2)c2cccc(N(c3ccccc3)c3ccc4c(c3)B3c5ccccc5N(c5ccccc5)c5cccc(c53)N4c3ccccc3)c2)cc1 ; c1ccc(N2c3ccccc3B3c4ccc5c(oc6ccccc65)c4N(c4ccccc4)c4cccc2c43)cc1 ; CC(C)(C)c1cc2c3c(c1)N(c1ccccc1)c1ccccc1B3c1cc(N(c3ccccc3)c3cccc(N(c4ccccc4)c4ccccc4)c3)ccc1O2]

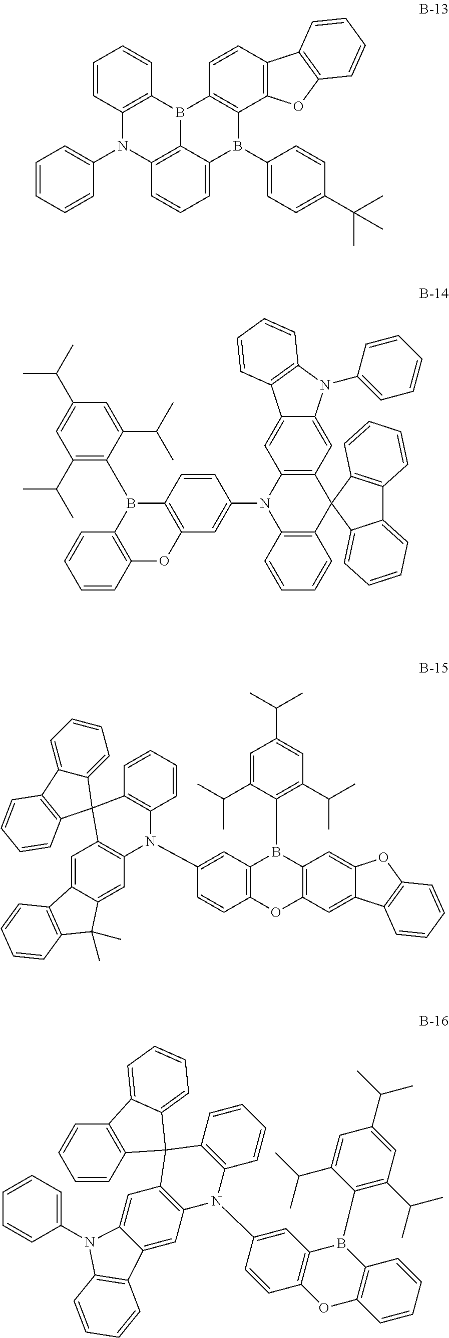

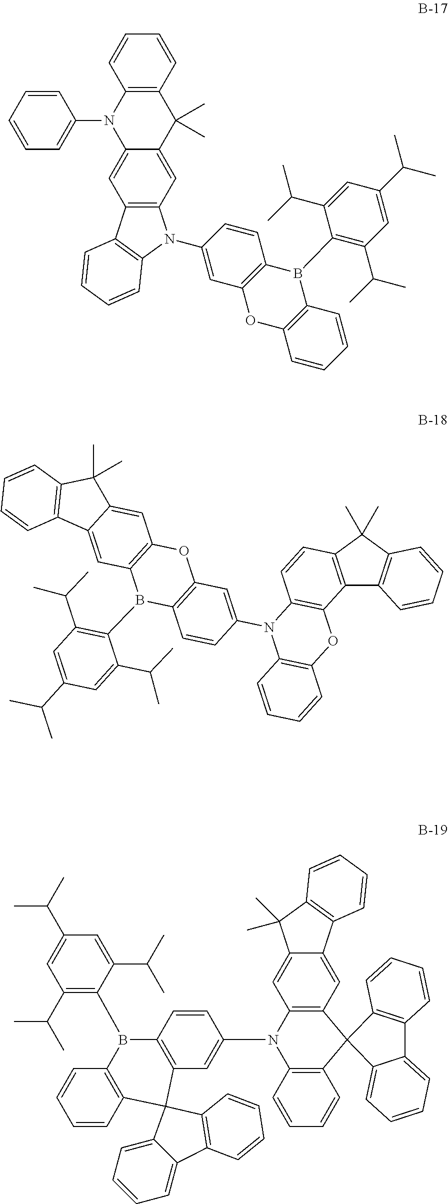

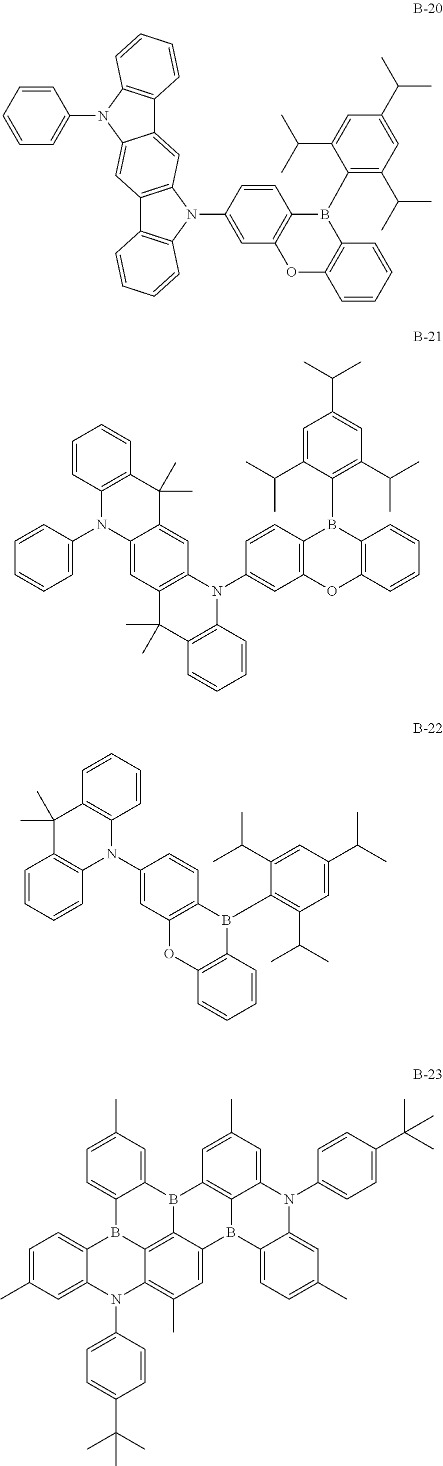

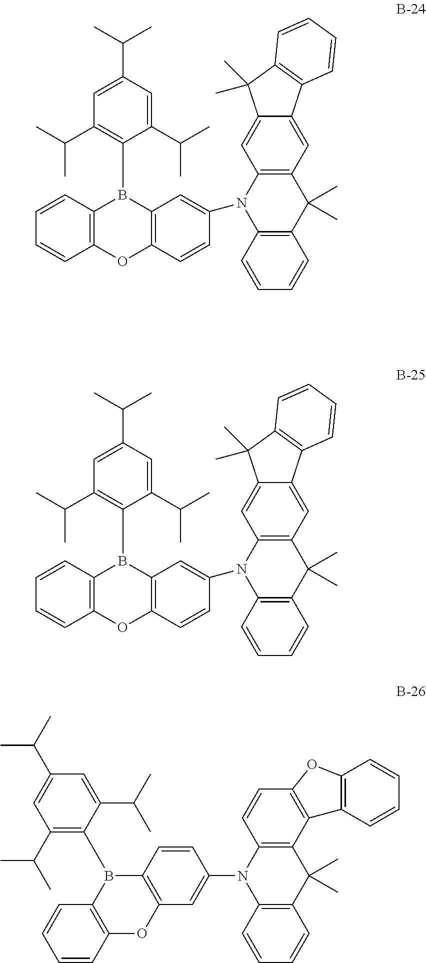

In a preferred embodiment, the fluorescent material is selected from the following compounds:

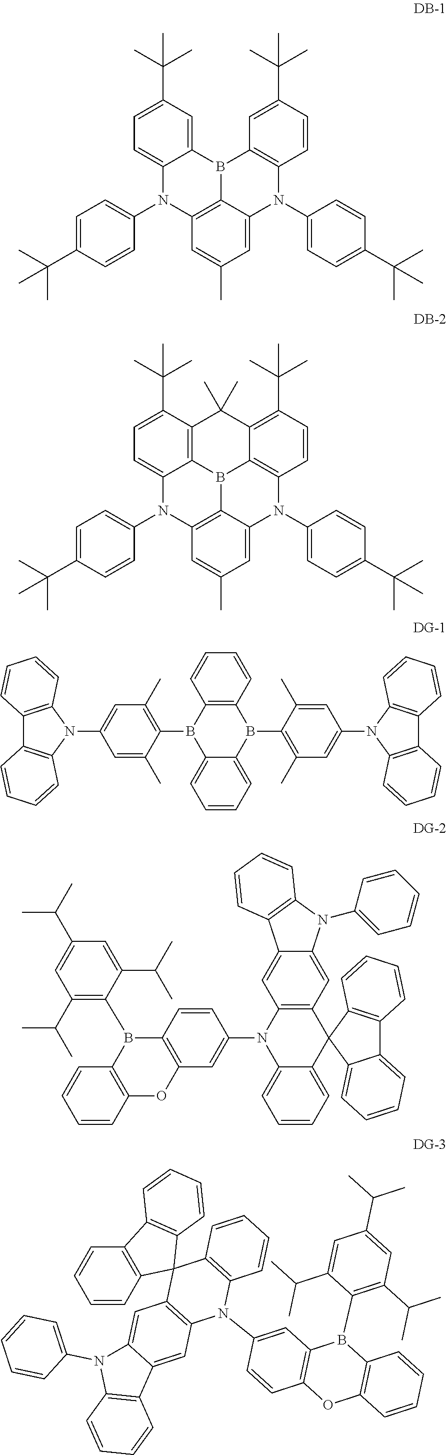

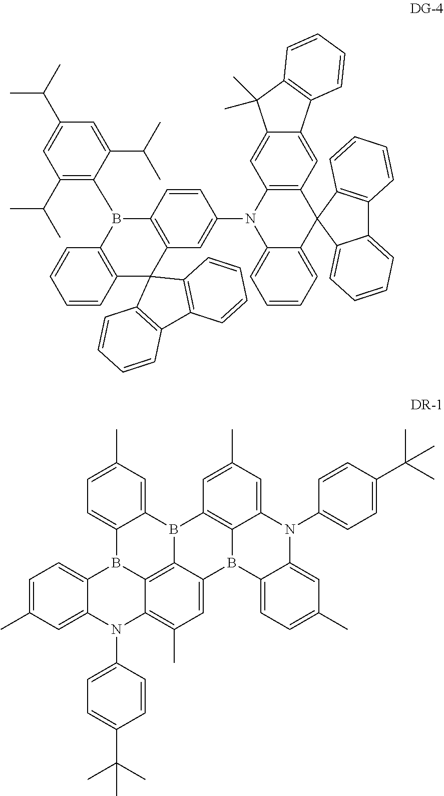 [SMILES: CC(C)c1cc(C(C)C)c(B2c3ccccc3C3(c4cc(N5c6ccccc6C6(c7ccccc7-c7ccccc76)c6cc7c(cc65)C(C)(C)c5ccccc5-7)ccc42)c2ccccc2-c2ccccc23)c(C(C)C)c1 ; Cc1ccc2c(c1)B1c3cc(C)cc4c3B(c3ccc(C)cc3N4c3ccc(C(C)(C)C)cc3)c3cc(C)c4c(c31)B2c1ccc(C)cc1N4c1ccc(C(C)(C)C)cc1]

In a preferred embodiment, the mass percentage of the fluorescent material relative to the host material is 1˜5%, preferably 1˜3%;

In a preferred embodiment, the mass percentage of the fluorescent material relative to the host material is 5˜30%, preferably 5˜10%;

For the mixture or interface formed by the first organic compound and the second organic compound and the preferred fluorescent material, the former's emission spectrums (including optical excitation emission spectrum and electric field excitation emission spectrum) and the latter's absorption spectrum are tested in the film state respectively. The details are shown in FIGS. 2-5.

It can be seen from FIGS. 2-4 that the mixture or interface formed by the first organic compound and the second organic compound generates the exciplex under optical excitation or electric field excitation (the spectrum is in red shift and the peak shape is broadened); however, some of them generates the exciplex under electric excitation, while no exciplex is generated under optical excitation (a mixture or interface formed by H3 and H9). FIG. 5 is an ultraviolet absorption spectrum of a fluorescent doping material. It can be seen that the longest wavelength absorption spectrum of the fluorescent doping material are overlapped with the emission spectrum of the exciplex, which ensures the sufficiency of energy transfer.

On the other hand, the organic electroluminescent device of the disclosure also comprises a negative electrode and a positive electrode.

In a preferred embodiment, the positive electrode comprises a metal, a metal oxide or a conducting polymer. For example, the work function of the positive electrode ranges from about 3.5 eV to about 5.5 eV. Illustrative examples of the conducting materials for the positive electrode comprise carbon, aluminum, vanadium, chromium, copper, zinc, silver, gold, other metals and their alloys; zinc oxide, indium oxide, tin oxide, indium tin oxide (ITO), indium zinc oxide and other similar metal oxides; and mixtures of oxide and metal, for example ZnO:Al and SnO₂:Sb. Both of transparent and non-transparent materials can be used as positive electrode materials for example polyimide (PI). For a structure emitting light to the positive electrode, a transparent positive electrode can be formed. In this paper, transparency means the pervious degree of light emitted from an organic material layer, and the light perviousness has no specific limitation.

For example, when the organic light-emitting device described in this specification is of a top light-emitting type and the positive electrode is formed on a substrate before the organic material layer and the negative electrode are formed, both of the transparent materials and non-transparent materials having excellent light reflection can be used as positive electrode materials, for example alloy formed by magnesium and silver is used as the negative electrode. In another embodiment, when the organic light-emitting device in this specification is of a bottom light-emitting type and the positive electrode is formed on the substrate before the organic material layer and the negative electrode are formed, it is needed that the transparent material is used as the positive material, or the non-transparent material needs to be formed into a film which is thin enough to be transparent.

In a preferred embodiment, for the negative electrode, a material with a small work function is preferred as the negative electrode material so that electron injection can be easily conducted.

For example, in this specification, materials with work functions ranging from 2 eV to 5 eV can be used as negative electrode materials. The negative electrode can include metals such as magnesium, calcium, sodium, potassium, titanium, indium, yttrium, lithium, gadolinium, aluminum, silver, tin and lead or alloys thereof; materials having a multilayer structure, such as LiF/Al or LiO₂/Al, but are not limited to thereto.

The negative electrode can be made from the same material as that of the positive electrode. In this case, the negative electrode can be formed using the positive electrode material as described above. In addition, the negative electrode or the positive electrode can contain the transparent material.

According to the used material, the organic light-emitting device of the disclosure can be of top light-emitting type, bottom light-emitting type or two-side light-emitting type.

In a preferred embodiment, the organic light-emitting device of the disclosure comprises a hole injection layer. The hole injection layer can be preferably disposed between the positive electrode and the luminescent layer. The hole injection layer is formed from a hole injection material known to those skilled in the art. The hole injection material is a material which can easily receive holes from the positive electrode under low voltage, and the HOMO of the hole injection material is preferably located between the work function of the positive electrode material and the HOMO of a surrounding organic material layer. Specific examples of the hole injection materials include, but are not limited to, metalloporphyrin organic materials, oligothiophene organic materials, aromatic amine organic materials, hexanitrile hexaazabenzophenanthrene organic materials, quinacridone organic materials, perylene organic materials, anthraquinone conducting polymers, polyaniline conducting polymers or polythiophene conducting polymers, such as HAT-CN and NPB.

In a preferred embodiment, the organic light-emitting device of the disclosure comprises a hole transport layer. The hole transport layer can be preferably disposed between the hole injection layer and the luminescent layer, or between the positive electrode and the luminescent layer. The hole transport layer is formed from a hole transport material known to those skilled in the art. The hole transport material is preferably a material with high hole mobility, which can transfer holes from the positive electrode or hole injection layer to the luminescent layer. Specific examples of hole transport materials include, but are not limited to, aromatic amine organic materials, conducting polymers, and block copolymers with jointing portions and non-jointing portions.

In a preferred embodiment, the organic light-emitting device of the disclosure also comprises an electron barrier layer. The electron barrier layer can be preferably disposed between the hole transport layer and the luminescent layer, or between the hole injection layer and the luminescent layer, or between the positive electrode and the luminescent layer. The electron barrier layer is formed from an electron barrier material, such as TCTA, known to those skilled in the art.

In a preferred embodiment, the organic light-emitting device of the disclosure comprises an electron injection layer. The electron injection layer can be preferably disposed between the negative electrode and the luminescent layer. The electron injection layer is formed from an electron injection material known to those skilled in the art. The electron injection layer can be formed using, for example, an electron receiving organic compound. Here, as the electron acceptor organic compound, the known and optional compound can be used without special limitations. As such the organic compounds, polycyclic compounds, such as p-terphenyl or quaterphenyl or derivatives thereof; polycyclic hydrocarbon compounds, such as naphthalene, tetracene, perylene, hexabenzobenzene, chrysene, anthracene, diphenylanthracene or phenanthrene, or derivatives thereof; or heterocyclic compounds, such as phenanthroline, bathophenanthroline, phenanthridine, acridine, quinoline, quinoxaline or phenazine, or derivatives thereof. The electron injection layer can also be formed using inorganic compounds, including but not limited to, magnesium, calcium, sodium, potassium, titanium, indium, yttrium, lithium, gadolinium, ytterbium, aluminum, silver, tin and lead or their alloys; LiF, LiO₂, LiCoO₂, NaCl, MgF₂, CSF, CaF₂, BaF₂, NaF, RbF, CsCl, Ru₂CO₃, YbF₃; and materials with multilayer structures, such as LiF/Al or LiO₂/Al.

In a preferred embodiment, the organic light-emitting device of the disclosure comprises an electron transport layer. The electron transport layer can be preferably disposed between the electron injection layer and the luminescent layer, or between the negative electrode and the luminescent layer. The electron transport layer is formed from an electron transport material known to those skilled in the art. The electron transport material is a material that can easily receive electrons from the negative electrode and transfer the received electrons to the luminescent layer. Materials with high electron mobility are preferred. Specific examples of the electron transport materials include, but are not limited to, 8-hydroxyquinoline aluminum complexes; complexes containing 8-hydroxyquinoline aluminum; organic free radical compounds; and hydroxyflavone metal complexes; and TPBi.

In a preferred embodiment, the organic light-emitting device of the disclosure also comprises a hole barrier layer. The hole barrier layer can be preferably disposed between the electron transport layer and the luminescent layer, or between the electron injection layer and the luminescent layer, or between the negative electrode and the luminescent layer. The hole barrier layer is a layer that prevents the injected holes from passing through the luminescent layer to the negative electrode, and usually can be formed under the same conditions as the hole injection layer. Specific examples include oxadiazole derivatives, triazole derivatives, phenanthroline derivatives, BCP, aluminum complexes, but are not limited to thereto.

In a preferred embodiment, the hole barrier layer can be the same as the electron transport layer.

In addition, according to another embodiment of this specification, the organic light-emitting device can also comprise a substrate. Specifically, in the organic light-emitting device, the positive electrode or negative electrode can be provided on the substrate. For the substrate, there is no special limitation. The substrate is a rigid substrate, such as a glass substrate, can also be a flexible substrate, such as a flexible film-shaped glass substrate, a plastic substrate or a film-shaped substrate.

The organic light-emitting device of the disclosure can be produced using the same materials and methods known in the art. Specifically, the organic light-emitting device can be produced by depositing metals, conducting metal oxides or their alloys on the substrate using a physical vapor deposition (PVD) method (e.g., sputtering or electron beam evaporation) to form the positive electrode, forming an organic material layer comprising the hole injection layer, the hole transport layer, the electron barrier layer, the luminescent layer and the electron transport layer on the positive electrode and subsequently depositing a material that can be used to form the negative electrode. In addition, the organic light-emitting device can be fabricated by sequentially depositing the negative electrode material, one or more organic material layers and the positive electrode material on the substrate. In addition, during the manufacturing of the organic light-emitting device, except the physical vapor deposition method, the organic light-emitting composite material of the disclosure can be made into the organic material layer by using a solution coating method. As used in this specification, the term “solution coating” refers to rotary coating, dip coating, scraper coating, inkjet printing, screen printing, spraying, roller coating, but is not limited to thereto.

As for the thickness of each layer, there are no specific limitations, it can be determined by those skilled in the art according to the needs and specific circumstances.

In a preferred embodiment, the thickness of the luminescent layer and the thicknesses of the optional hole injection layer, hole transport layer, electron barrier layer, electron transport layer and electron injection layer are respectively 0.5˜150 nm, preferably 1˜100 nm.

In a preferred embodiment, the thickness of the luminescent layer is 20˜80 nm, preferably 30˜60 nm.

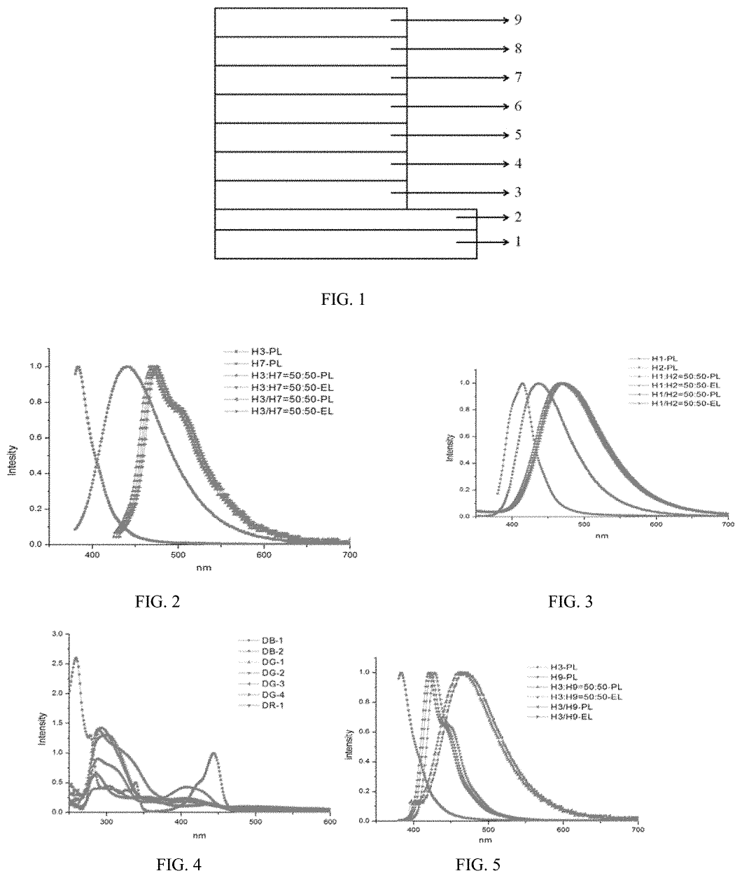

The organic electroluminescent device of the disclosure has the advantages of higher device efficiency and longer device lifetime. The disclosure will be specifically described in combination with FIG. 1 and examples, but the scope of the disclosure is not limited by these preparation examples.

### Example 1

The structure of the organic electroluminescent device prepared in example 1 is as shown in FIG. 1, and the specific preparation process of the device is as follows:

An ITO positive electrode layer 2 on a transparent glass substrate layer 1 was washed by ultrasonic cleaning with deionized water, acetone and ethanol for 30 minutes respectively, and then treated in a plasma washer for 2 minutes; the ITO glass substrate was dried and then placed in a vacuum chamber until the vacuum degree was less than 1*10⁻⁶ Torr, an HT1 and P1 mixture having a thickness of 10 nm was evaporated on the ITO positive electrode layer 2, the mass ratio of HT1 to P1 was 97:3, and this layer was a hole injection layer 3; then, HT1 having a thickness of 50 nm was evaporated as a hole transport layer 4; then, EB1 having a thickness of 20 nm was evaporated as an electron barrier layer 5; further, a luminescent layer 6 having a thickness of 25 nm was evaporated, wherein the luminescent layer included a host material and guest doping dye. The selection of specific materials is shown in Table 3. According to the mass percentages of the host material and the doping dye, the rate control was conducted through a film thickness gauge; ET1 and Liq having a thickness of 40 nm were further evaporated on the luminescent layer 6, and the mass ratio of ET1 to Liq was 1:1, and this organic material layer was used as a hole barrier/electron transport layer 7; LiF having a thickness of 1 nm was evaporated on the hole barrier/electron transport layer 7 in vacuum, which was an electron injection layer 8; the negative electrode Al (80 nm) was evaporated in vacuum on the electron injection layer 8, which was a negative electrode layer 9. Different devices had different evaporated film thicknesses. The selection of specific materials in example 1 is shown in Table 3.

### Examples 2˜21

the preparation methods are similar to the preparation method of example 1. The selection of specific materials in example 1 is shown in Table 3.

### Comparative Examples 1˜14

the preparation methods are similar to the preparation method of example 1. The difference from comparative example 1 is that the types, film thickness or proportion of a functional layer in comparative example 2 are changed. The specific materials are shown in Table 3.

| | | | Hole | Hole | Electron | | Hole | Electron | |
|---|---|---|---|---|---|---|---|---|---|
| | | Positive | injection | transport | barrier | Luminescent | barrier | injection | Negative |
| Number | Substrate | electrode | layer | layer | layer | layer | layer | layer | electrode |
| Comparative | Glass | ITO | HT1:P1 | HT1 | EB1 | H3:BD-1 = | ET1:Liq | LiF | Al |
| example 1 | | | (10 nm) | (50 nm) | (20 nm) | 100:5 | (40 nm) | (1 nm) | (80 nm) |
| | | | | | | (25 nm) | | | |
| Comparative | Glass | ITO | HT1:P1 | HT1 | EB1 | H7:BD-1 = | ET1:Liq | LiF | Al |
| example 2 | | | (10 nm) | (50 nm) | (20 nm) | 100:5 | (40 nm) | (1 nm) | (80 nm) |
| | | | | | | (25 nm) | | | |
| Example 1 | Glass | ITO | HT1:P1 | HT1 | EB1 | H3:H7:BD-1 = | ET1:Liq | LiF | Al |
| | | | (10 nm) | (50 nm) | (20 nm) | 50:50:5 | (40 nm) | (1 nm) | (80 nm) |
| | | | | | | (25 nm) | | | |
| Example | Glass | ITO | HT1:P1 | HT1 | EB1 | H3:H7:BD-1 = | ET1:Liq | LiF | Al |
| 1-1 | | | (10 nm) | (50 nm) | (20 nm) | 60:40:5 | (40 nm) | (1 nm) | (80 nm) |
| | | | | | | (25 nm) | | | |
| Example | Glass | ITO | HT1:P1 | HT1 | EB1 | H3:H7:BD-1 = | ET1:Liq | / | Mg:Ag = |
| 1-2 | | | (10 nm) | (50 nm) | (20 nm) | 60:40:5 | (40 nm) | | 10:1 |
| | | | | | | (25 nm) | | | (15 nm) |
| Example 2 | Glass | ITO | HT1:P1 | HT1 | EB1 | H3 (12.5 nm)/ | ET1:Liq | LiF | Al |
| | | | (10 nm) | (50 nm) | (20 nm) | H7:BD-1 = | (40 nm) | (1 nm) | (80 nm) |
| | | | | | | 100:5 | | | |
| | | | | | | (12.5 nm) | | | |
| Example 3 | Glass | ITO | HT1:P1 | HT1 | EB1 | H3:BD-1 = | ET1:Liq | LiF | Al |
| | | | (10 nm) | (50 nm) | (20 nm) | 100:5 | (40 nm) | (1 nm) | (80 nm) |
| | | | | | | (12.5 nm)/ | | | |
| | | | | | | H7 (12.5 nm) | | | |
| Comparative | Glass | ITO | HT1:P1 | HT1 | EB1 | H3:BD-2 = | ET1:Liq | LiF | Al |
| example 3 | | | (10 nm) | (50 nm) | (20 nm) | 100:5 | (40 nm) | (1 nm) | (80 nm) |
| | | | | | | (25 nm) | | | |
| Comparative | Glass | ITO | HT1:P1 | HT1 | EB1 | H7:BD-2 = | ET1:Liq | LiF | Al |
| example 4 | | | (10 nm) | (50 nm) | (20 nm) | 100:5 | (40 nm) | (1 nm) | (80 nm) |
| | | | | | | (25 nm) | | | |
| Example 4 | Glass | ITO | HT1:P1 | HT1 | EB1 | H3:H7:BD-2 = | ET1:Liq | LiF | Al |
| | | | (10 nm) | (50 nm) | (20 nm) | 50:50:5 | (40 nm) | (1 nm) | (80 nm) |
| | | | | | | (25 nm) | | | |
| Example | Glass | ITO | HT1:P1 | HT1 | EB1 | H3:H7:BD-2 = | ET1:Liq | LiF | Al |
| 4-1 | | | (10 nm) | (50 nm) | (20 nm) | 60:40:5 | (40 nm) | (1 nm) | (80 nm) |
| | | | | | | (25 nm) | | | |
| Example | Polyimide | ITO | HT1:P1 | HT1 | EB1 | H3:H7:BD-2 = | ET1:Liq | LiF | Al |
| 4-2 | | | (10 nm) | (50 nm) | (20 nm) | 50:50:5 | (40 nm) | (1 nm) | (80 nm) |
| | | | | | | (25 nm) | | | |
| Example | Glass | ITO | HT1:P1 | HT1 | EB1 | H3:H7:BD-2= | ET1:Liq | / | Mg:Ag = |
| 4-3 | | | (10 nm) | (50 nm) | (20 nm) | 50:50:5 | (40 nm) | | 10:1 |
| | | | | | | (25 nm) | | | (15 nm) |
| Example | Glass | ITO | HT1:P1 | HT1 | EB1 | H3:H7:BD-2= | ET1:Liq | CaF₂ | Ca |
| 4-4 | | | (10 nm) | (50 nm) | (20 nm) | 50:50:5 | (40 nm) | (1 nm) | (80 nm) |
| | | | | | | (25 nm) | | | |
| Example | Glass | ITO | HT1:P1 | HT1 | EB1 | H3:H7:BD-2= | ET1:Liq | LiF | Al |
| 4-5 | | | (10 nm) | (50 nm) | (20 nm) | 50:50:8 | (40 nm) | (1 nm) | (80 nm) |
| | | | | | | (25 nm) | | | |
| Example 5 | Glass | ITO | HT1:P1 | HT1 | EB1 | H3 (12.5 nm)/ | ET1:Liq | LiF | Al |
| | | | (10 nm) | (50 nm) | (20 nm) | H7:BD-2 = | (40 nm) | (1 nm) | (80 nm) |
| | | | | | | 100:5 | | | |
| | | | | | | (12.5 nm) | | | |
| Example 6 | Glass | ITO | HT1:P1 | HT1 | EB1 | H3:BD-2 = | ET1:Liq | LiF | Al |
| | | | (10 nm) | (50 nm) | (20 nm) | 100:5 | (40 nm) | (1 nm) | (80 nm) |
| | | | | | | (12.5 nm)/ | | | |
| | | | | | | H7 (12.5 nm) | | | |
| Comparative | Glass | ITO | HT1:P1 | HT1 | EB1 | H2:DG-1 = | ET1:Liq | LiF | Al |
| example 5 | | | (10 nm) | (50 nm) | (60 nm) | 100:12 | (40 nm) | (1 nm) | (80 nm) |
| | | | | | | (40 nm) | | | |
| Comparative | Glass | ITO | HT1:P1 | HT1 | EB1 | H1:DG-1 = | ET1:Liq | LiF | Al |
| example 6 | | | (10 nm) | (50 nm) | (60 nm) | 100:12 | (40 nm) | (1 nm) | (80 nm) |
| | | | | | | (40 nm) | | | |
| Example 7 | Glass | ITO | HT1:P1 | HT1 | EB1 | H2:H1:DG-1 = | ET1:Liq | LiF | Al |
| | | | (10 nm) | (50 nm) | (60 nm) | 50:50:12 | (40 nm) | (1 nm) | (80 nm) |
| | | | | | | (40 nm) | | | |
| Example 8 | Glass | ITO | HT1:P1 | HT1 | EB1 | H2 (20 nm)/ | ET1:Liq | LiF | Al |
| | | | (10 nm) | (50 nm) | (60 nm) | H1:DG-1 = | (40 nm) | (1 nm) | (80 nm) |
| | | | | | | 100:12 | | | |
| | | | | | | (20 nm) | | | |
| Example 9 | Glass | ITO | HT1:P1 | HT1 | EB1 | H2:DG-1 = | ET1:Liq | LiF | Al |
| | | | (10 nm) | (50 nm) | (60 nm) | 100:12 | (40 nm) | (1 nm) | (80 nm) |
| | | | | | | (20 nm)/ | | | |
| | | | | | | H1 (20 nm) | | | |
| Comparative | Glass | ITO | HT1:P1 | HT1 | EB1 | H2:DG-2 = | ET1:Liq | LiF | Al |
| example 7 | | | (10 nm) | (50 nm) | (60 nm) | 100:12 | (40 nm) | (1 nm) | (80 nm) |
| | | | | | | (40 nm) | | | |
| Comparative | Glass | ITO | HT1:P1 | HT1 | EB1 | H1:DG-2 = | ET1:Liq | LiF | Al |
| example 8 | | | (10 nm) | (50 nm) | (60 nm) | 100:12 | (40 nm) | (1 nm) | (80 nm) |
| | | | | | | (40 nm) | | | |
| Example 10 | Glass | ITO | HT1:P1 | HT1 | EB1 | H2:H1:DG-2 = | ET1:Liq | LiF | Al |
| | | | (10 nm) | (50 nm) | (60 nm) | 50:50:12 | (40 nm) | (1 nm) | (80 nm) |
| | | | | | | (40 nm) | | | |
| Example 11 | Glass | ITO | HT1:P1 | HT1 | EB1 | H2 (20 nm)/ | ET1:Liq | LiF | Al |
| | | | (10 nm) | (50 nm) | (60 nm) | H1:DG-2 = | (40 nm) | (1 nm) | (80 nm) |
| | | | | | | 100:12 | | | |
| | | | | | | (20 nm) | | | |
| Example 12 | Glass | ITO | HT1:P1 | HT1 | EB1 | H2:DG-2 = | ET1:Liq | LiF | Al |
| | | | (10 nm) | (50 nm) | (60 nm) | 100:12 | (40 nm) | (1 nm) | (80 nm) |
| | | | | | | (20 nm)/ | | | |
| | | | | | | H1 (20 nm) | | | |
| Comparative | Glass | ITO | HT1:P1 | HT1 | EB1 | H2:DG-3 = | ET1:Liq | LiF | Al |
| example 9 | | | (10 nm) | (50 nm) | (60 nm) | 100:12 | (40 nm) | (1 nm) | (80 nm) |
| | | | | | | (40 nm) | | | |
| Comparative | Glass | ITO | HT1:P1 | HT1 | EB1 | H1:DG-3 = | ET1:Liq | LiF | Al |
| example 10 | | | (10 nm) | (50 nm) | (60 nm) | 100:12 | (40 nm) | (1 nm) | (80 nm) |
| | | | | | | (40 nm) | | | |
| Example 13 | Glass | ITO | HT1:P1 | HT1 | EB1 | H2:H1:DG-3 = | ET1:Liq | LiF | Al |
| | | | (10 nm) | (50 nm) | (60 nm) | 50:50:12 | (40 nm) | (1 nm) | (80 nm) |
| | | | | | | (40 nm) | | | |
| Example 14 | Glass | ITO | HT1:P1 | HT1 | EB1 | H2 (20 nm)/ | ET1:Liq | LiF | Al |
| | | | (10 nm) | (50 nm) | (60 nm) | H1:DG-3 = | (40 nm) | (1 nm) | (80 nm) |
| | | | | | | 100:12 | | | |
| | | | | | | (20 nm) | | | |
| Example 15 | glass | ITO | HT1:P1 | HT1 | EB1 | H2:DG-3 = | ET1:Liq | LiF | Al |
| | | | (10 nm) | (50 nm) | (60 nm) | 100:12 | (40 nm) | (1 nm) | (80 nm) |
| | | | | | | (20 nm)/ | | | |
| | | | | | | H1 (20 nm) | | | |
| Comparative | Glass | ITO | HT1:P1 | HT1 | EB1 | H2:DG-4 = | ET1:Liq | LiF | Al |
| example 11 | | | (10 nm) | (50 nm) | (60 nm) | 100:12 | (40 nm) | (1 nm) | (80 nm) |
| | | | | | | (40 nm) | | | |
| Comparative | Glass | ITO | HT1:P1 | HT1 | EB1 | H1:DG-4 = | ET1:Liq | LiF | Al |
| example 12 | | | (10 nm) | (50 nm) | (60 nm) | 100:12 | (40 nm) | (1 nm) | (80 nm) |
| | | | | | | (40 nm) | | | |
| Example 16 | Glass | ITO | HT1:P1 | HT1 | EB1 | H2:H1:DG-4 = | ET1:Liq | LiF | Al |
| | | | (10 nm) | (50 nm) | (60 nm) | 50:50:12 | (40 nm) | (1 nm) | (80 nm) |
| | | | | | | (40 nm) | | | |
| Example 17 | Glass | ITO | HT1:P1 | HT1 | EB1 | H2 (20 nm)/ | ET1:Liq | LiF | Al |
| | | | (10 nm) | (50 nm) | (60 nm) | H1:DG-4 = | (40 nm) | (1 nm) | (80 nm) |
| | | | | | | 100:12 | | | |
| | | | | | | (20 nm) | | | |
| Example 18 | Glass | ITO | HT1:P1 | HT1 | EB1 | H2:DG-4 = | ET1:Liq | LiF | Al |
| | | | (10 nm) | (50 nm) | (60 nm) | 100:12 | (40 nm) | (1 nm) | (80 nm) |
| | | | | | | (20 nm)/ | | | |
| | | | | | | H1 (20 nm) | | | |
| Comparative | Glass | ITO | HT1:P1 | HT1 | EB1 | H9:DR-1 = | ET1:Liq | LiF | Al |
| example 13 | | | (10 nm) | (50 nm) | (110 nm) | 100:10 | (40 nm) | (1 nm) | (80 nm) |
| | | | | | | (40 nm) | | | |
| Comparative | Glass | ITO | HT1:P1 | HT1 | EB1 | H3:DR-1 = | ET1:Liq | LiF | Al |
| example 14 | | | (10 nm) | (50 nm) | (110 nm) | 100:10 | (40 nm) | (1 nm) | (80 nm) |
| | | | | | | (40 nm) | | | |
| Example 19 | Glass | ITO | HT1:P1 | HT1 | EB1 | H3:H9:DR-1 = | ET1:Liq | LiF | Al |
| | | | (10 nm) | (50 nm) | (110 nm) | 50:50:10 | (40 nm) | (1 nm) | (80 nm) |
| | | | | | | (40 nm) | | | |
| Example 20 | Glass | ITO | HT1:P1 | HT1 | EB1 | H3 (20 nm)/ | ET1:Liq | LiF | Al |
| | | | (10 nm) | (50 nm) | (110 nm) | H9:DR-1 = | (40 nm) | (1 nm) | (80 nm) |
| | | | | | | 100:10 | | | |
| | | | | | | (20 nm) | | | |
| Example 21 | Glass | ITO | HT1:P1 | HT1 | EB1 | H3:DR-1 = | ET1:Liq | LiF | Al |
| | | | (10 nm) | (50 nm) | (110 nm) | 100:10 | (40 nm) | (1 nm) | (80 nm) |
| | | | | | | (20 nm)/ | | | |
| | | | | | | H9 (20 nm) | | | |

It is necessary to explain that the double hosts in the disclosure has two representation forms: one is that the first organic compound and the second organic compound form a certain proportion of mixture through the form of double sources co-evaporation, and the guest material is doped in the mixture formed by the two, for example, H2: H1: DG-4=50:50:12 (40 nm); the other double-host form is that the first organic compound or the second organic compound is evaporated firstly, and then the second organic compound or the first organic compound is evaporated to form the superimposed structure of the interface. The guest material is doped in the first organic compound or the second organic compound, such as H3 (20 nm)/H9:DR-1=100:10 (20 nm) or H3: DR-1=100:10 (20 nm)/H9 (20 nm).

The raw materials H1-H9 mentioned in Table 3 are as shown above, and the structural formulas of other materials are as follows:

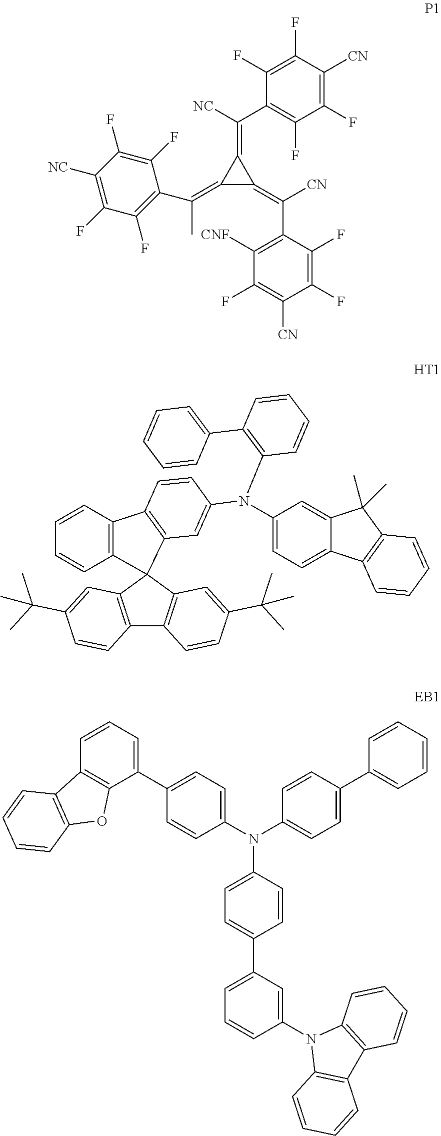

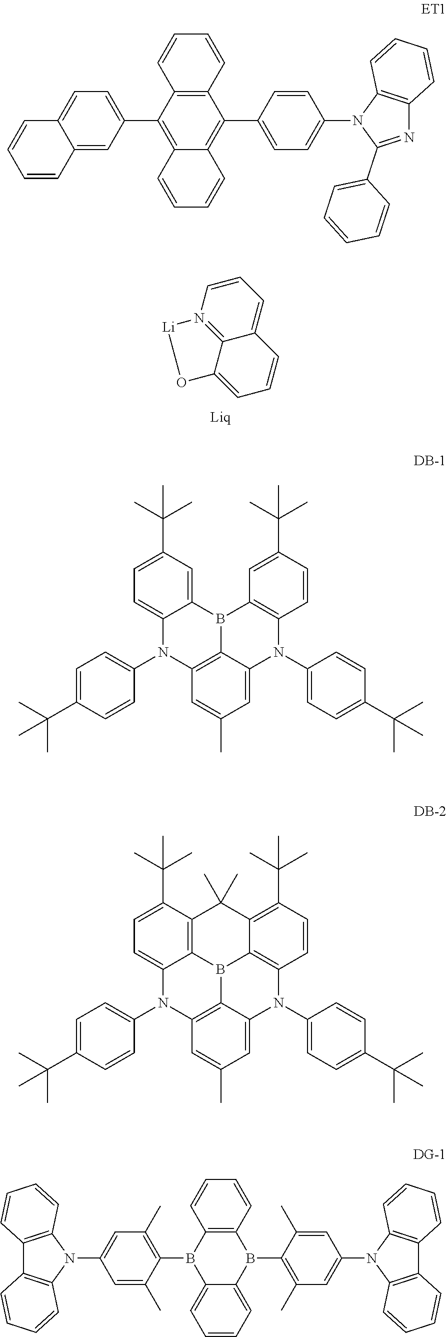

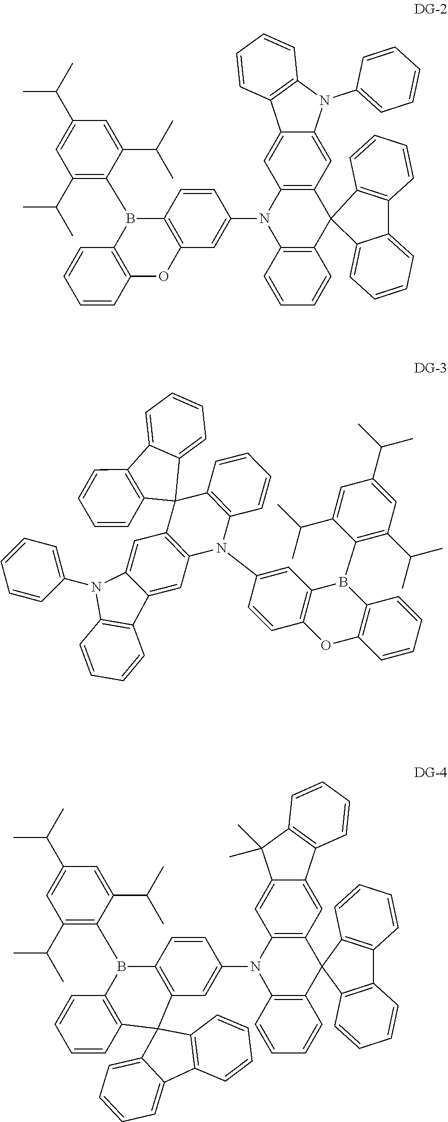

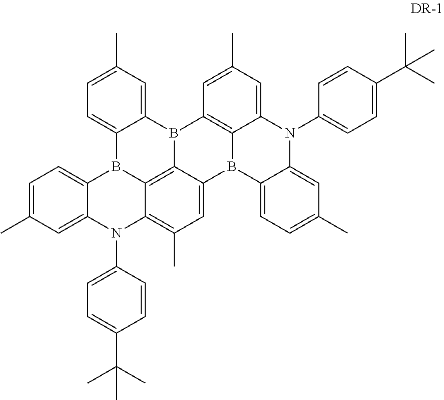 [SMILES: Cc1ccc2c(c1)B1c3cc(C)cc4c3B(c3ccc(C)cc3N4c3ccc(C(C)(C)C)cc3)c3cc(C)c4c(c31)B2c1ccc(C)cc1N4c1ccc(C(C)(C)C)cc1]

Among them, the energy level relationship of host and guest materials is as follows:

H1:HOMO is −5.82 eV, LUMO is −2.80 eV, S1 is 2.92 eV, T1 is 2.77 eV;

H2:HOMO is −5.60 eV, LUMO is −2.17 eV, S1 is 3.23 eV, T1 is 2.76 eV;

H3:HOMO is −6.01 eV, LUMO is −2.58 eV, S1 is 3.53 eV, T1 is 2.86 eV;

H4:HOMO is −6.23 eV, LUMO is −2.64 eV, S1 is 3.46 eV, T1 is 2.63 eV;

H5:HOMO is −5.64 eV, LUMO is −2.27 eV, S1 is 3.28 eV, T1 is 2.71 eV;

H6:HOMO is −5.78 eV, LUMO is −2.50 eV, S1 is 3.40 eV, T1 is 2.77 eV;

H7:HOMO is −6.48 eV, LUMO is −2.89 eV, S1 is 3.54 eV, T1 is 2.72 eV;

H8:HOMO is −5.57 eV, LUMO is −2.25 eV, S1 is 3.19 eV, T1 is 2.62 eV;

H9:HOMO is −6.52 eV, LUMO is −3.43 eV, S1 is 3.22 eV, T1 is 2.50 eV;

TAPC:HOMO is 5.6 eV, LUMO is 2.03 eV, S1 is 3.3 eV, T1 is 2.6 eV

TCTA:HOMO is 5.81 eV, LUMO is 2.44 eV, S1 is 3.5 eV, T1 is 2.7 eV

TPBi:HOMO is 6.44 eV, LUMO is 2.92 eV, S1 is 3.6 eV, T1 is 2.9 eV

BD-1:HOMO is 5.48 eV, LUMO is 2.78 eV, S1 is 2.73 eV, T1 is 2.63 eV;

BD-2:HOMO is 5.70 eV, LUMO is 2.85 eV, S1 is 2.80 eV, T1 is 2.65 eV;

DG-1:HOMO is 5.90 eV, LUMO is 3.40 eV, S1 is 2.40 eV, T1 is 2.30 eV;

DG-2:HOMO is 5.50 eV, LUMO is 2.85 eV, S1 is 2.40 eV, T1 is 2.30 eV;

DG-3:HOMO is 5.40 eV, LUMO is 2.76 eV, S1 is 2.38 eV, T1 is 2.33 eV;

DG-4:HOMO is 5.58 eV, LUMO is 2.77 eV, S1 is 2.44 eV, T1 is 2.37 eV;

DR-1:HOMO is 5.30 eV, LUMO is 3.35 eV, S1 is 2.15 eV, T1 is 2.04 eV

The organic electroluminescent devices prepared by examples and comparative examples were subjected to IVL data, light brightness attenuation lifetime and other performance tests. The results are as shown in Table 4.

TABLE 4

| | External | Maximum | | | |
|---|---|---|---|---|---|
| | quantum | external | LT90 | | Spectrum |
| Codes of | efficiency | quantum | lifetime | FWHM | Peak |
| devices | (10 mA/cm²) | efficiency | (h) | (nm) | (nm) |
| Comparative | 8.5 | 12.5 | 20 | 26 | 462 |
| example 1 | | | | | |
| Comparative | 8.1 | 12.2 | 16 | 27 | 463 |
| example 2 | | | | | |
| Example 1 | 14.8 | 19.5 | 100 | 26 | 463 |
| Example 1-1 | 10.6 | 15.9 | 50 | 26 | 462 |
| Example 1-2 | 10.2 | 15.4 | 35 | 28 | 464 |
| Example 2 | 14.0 | 18.6 | 130 | 26 | 462 |
| Example 3 | 13.5 | 18.8 | 110 | 27 | 463 |
| Comparative | 8.5 | 12.4 | 14 | 30 | 461 |
| example 3 | | | | | |
| Comparative | 8.4 | 12.6 | 16 | 29 | 460 |
| example 4 | | | | | |
| Example 4 | 13.6 | 18.9 | 120 | 29 | 461 |
| Example 4-1 | 13.5 | 18.7 | 125 | 28 | 462 |
| Example 4-2 | 13.1 | 18.5 | 130 | 30 | 461 |
| Example 4-3 | 13.8 | 19.2 | 150 | 23 | 460 |
| Example 4-4 | 13.4 | 19.4 | 110 | 29 | 461 |
| Example 4-5 | 13.6 | 19.6 | 114 | 30 | 462 |
| Example 5 | 14.0 | 19.4 | 107 | 30 | 462 |
| Example 6 | 13.7 | 19.2 | 111 | 31 | 461 |
| Comparative | 9.8 | 13.4 | 50 | 60 | 520 |
| example 5 | | | | | |
| Comparative | 9.2 | 13.5 | 55 | 58 | 521 |
| example 6 | | | | | |
| Example 7 | 14.3 | 20.5 | 200 | 59 | 521 |
| Example 8 | 15.3 | 21.0 | 230 | 60 | 522 |
| Example 9 | 15.0 | 20.8 | 221 | 61 | 521 |
| Comparative | 9.4 | 13.0 | 45 | 55 | 524 |
| example 7 | | | | | |
| Comparative | 9.6 | 13.4 | 40 | 54 | 524 |
| example 8 | | | | | |
| Example 10 | 15.3 | 20.2 | 204 | 54 | 525 |
| Example 11 | 15.0 | 20.1 | 220 | 53 | 523 |
| Example 12 | 14.9 | 19.5 | 226 | 54 | 523 |
| Comparative | 9.2 | 13.5 | 38 | 53 | 520 |
| example 9 | | | | | |
| Comparative | 8.8 | 13.2 | 45 | 52 | 519 |
| example 10 | | | | | |
| Example 13 | 14.3 | 19.5 | 251 | 52 | 519 |
| Example 14 | 13.9 | 19.2 | 244 | 51 | 520 |
| Example 15 | 13.4 | 18.9 | 238 | 52 | 520 |
| Comparative | 8.2 | 13.2 | 48 | 46 | 522 |
| example 11 | | | | | |
| Comparative | 9.0 | 13.0 | 40 | 45 | 521 |
| example 12 | | | | | |
| Example 16 | 15.0 | 20.3 | 268 | 47 | 521 |
| Example 17 | 15.2 | 20.1 | 245 | 48 | 522 |
| Example 18 | 14.3 | 19.5 | 253 | 48 | 522 |
| Comparative | 7.7 | 12.8 | 50 | 31 | 625 |
| example 13 | | | | | |
| Comparative | 7.6 | 13.1 | 55 | 30 | 624 |
| example 14 | | | | | |
| Example 19 | 12.0 | 18.6 | 256 | 29 | 625 |
| Example 20 | 12.8 | 18.8 | 285 | 30 | 623 |
| Example 21 | 12.5 | 18.5 | 272 | 29 | 624 |

It can be seen from data in the above table that by comparing examples 1˜21 with comparative examples 1˜14, the device using a single host material matched with the boron-containing material such as DB-1 and DB-2 is obviously inferior to the device matched with the double hosts for the main reasons are that the double host matching can balance the recombination rate of carriers and simultaneously reduce the concentration of excitons. In addition, due to the corresponding carrier transport characteristics, the double-host matched boron compound can form molecular oriented arrangement, which improves the light-emitting efficiency of the device. The structure is suitable for not only the blue light device, but also green light and red light devices, which indicates the universality of the matching.

The main reasons are that the host material of the luminescent layer is formed by matching two materials, the mixture or interface formed by the two materials generates an exciplex under the condition of optical excitation and electric excitation, thereby decreasing the concentration of the triplet excitons and reducing the quenching effect of the triplet excitons and improving the stability of the device. The second compound is a material having a carrier mobility different from that of the first compound, which can balance the carriers inside the host material, increase the recombination rate of excitons and improve the efficiency of the device, and meanwhile can effectively solve the shift problem of the material color under high current density so as to improve the stability of the light-emitting color of the device.

The formed exciplex has small triplet and singlet energy level difference so that the triplet excitons can be rapidly converted into the singlet excitons, thereby reducing the quenching effect of the triplet excitons and promoting the stability of the device. Meanwhile, the singlet energy level of the formed exciplex is higher than that of the fluorescent material, the triplet energy level of the formed exciplex is higher than that of the fluorescent material, thereby effectively preventing energy returning from the fluorescent material back to the host material and further improving the efficiency and stability of the device.

The fluorescent material containing boron atoms is bonded with other atoms through sp2 hybrid form of boron. In the formed structure, since boron is an electron deficient atom, it can form charge transfer state or reverse space resonance effect with an electron donating group or a weak electron withdrawing group, resulting in separation of HOMO and LUMO electron cloud orbits, reducing the difference between singlet-triplet energy levels of the material so as to generate a delayed fluorescence phenomenon; at the same time, the material with the boron atoms as a core can not only obtain very small singlet-triplet energy level difference, but also can effectively reduce the delayed fluorescence lifetime of the material due to its fast fluorescence radiation rate, thus reducing the triplet quenching effect and improving the efficiency of the device.

In addition, due to the existence of the boron atoms, the intra-molecular rigidity is enhanced, the molecular flexibility is reduced, the configuration difference between the ground state and excited state of the material is reduced effectively, and the FWHM of the light-emitting spectrum of the material is effectively reduced, which is conducive to improving the color purity of the device and improving the color gamut of the device. Therefore, the device structure matching of the disclosure can effectively promote the efficiency, lifetime and color purity of the device.

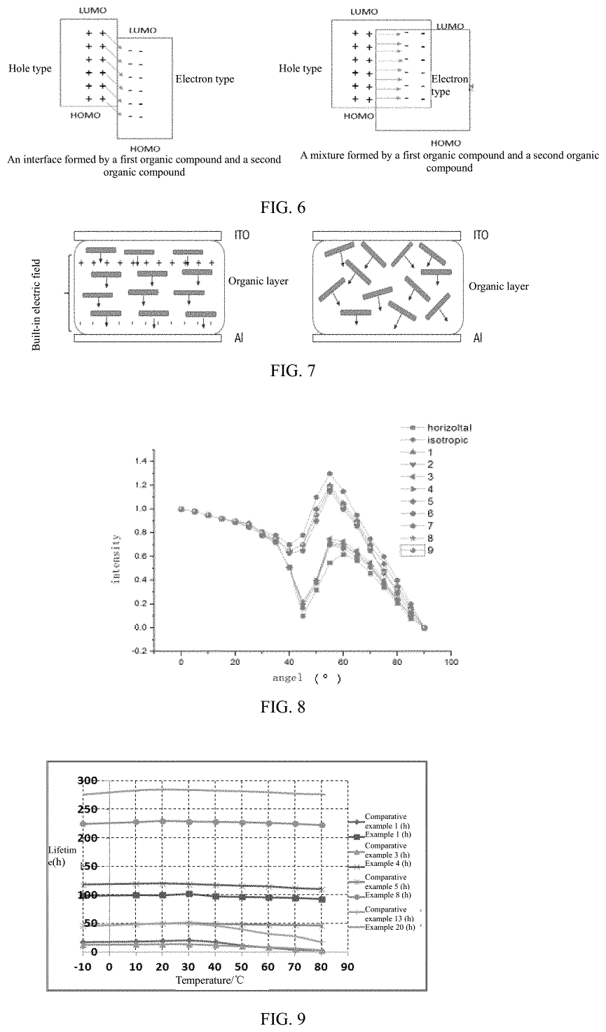

Furthermore, the applicant finds that due to different carrier transport characteristics of the first organic compound and the second organic compound, a stable built-in electric field is formed in the mixture or interface formed by the first organic compound of electron transfer type and the second organic compound of hole transfer type. At the same time, due to the electron deficiency of boron, molecular orientation combination arrangement can occur under the interaction between the built-in electric field and the boron atoms when the boron-containing compound is doped into the interface or mixture formed by the first organic compound and the second organic compound, so that the molecular arrangement of the boron-containing compound tends to be horizontal arrangement, and the light extraction rate of the material is improved, thereby improving the light-emitting efficiency of the device. However, the interface or mixture, which is formed by the single-host material and the first and second organic compounds with the same carrier attributes and matched with the boron-containing compound cannot generate the above effect, because it can not form the stable built-in electric field. In addition, the boron-containing compound can generate a strong acting force with the built-in electric field due to the extremely strong electron deficiency induction of the boron atom, so that the boron-containing compound generates molecular orientation rearrangement. The specific principle is shown in FIG. 6 and FIG. 7.

In order to further verify the above principle, the angle dependent spectrum of a single film (as shown in FIG. 8) can be tested. The horizontal dipole test results are shown in Table 5.

TABLE 5
Horizontal dipole proportion test result

| | | Horizontal |
|---|---|---|
| | | dipole |
| Number | Single film | proportion |
| 1 | H3:BD-1 = 100:3 (60 nm) | 0.60 |
| 2 | H7:BD-1 = 100:3 (60 nm) | 0.62 |
| 3 | H3:H7:BD-1 = 50:50:3 (60 nm) | 0.85 |
| 4 | H3 (30 nm)/H7:BD-1 = 100:3 (30 nm) | 0.87 |
| 5 | H3:H7:A-1 = 50:50:3 (60 nm) | 0.63 |
| 6 | H2:DG-1 = 100:12 (60 nm) | 0.60 |
| 7 | H2:H1:DG-1 = 50:50:12 (60 nm) | 0.88 |
| 8 | H2 (30 nm)/H1:DG-1 = 100:12 (30 nm) | 0.90 |
| 9 | H2:H1:A-2 = 50:50:12 (60 nm) | 0.61 |

It can be seen from FIG. 8 and table 5 that the mixture or interface formed by the first organic compound of electron transport type and the second organic compound of hole transport type is matched with the boron-containing compound, so that the proportion of horizontal molecular arrangement is obviously improved. The proportion of horizontal molecular arrangement of other matching forms is lower.

Further, the service lives of the OLED device prepared by the disclosure are relatively stable when working at different temperatures. The efficiencies of comparative example 1, example 1, comparative example 3, example 4, comparative example 5, example 8, comparative example 13 and example 20 of the device are tested at −10˜80° C. The results are shown in Table 6 and FIG. 9.

TABLE 6

| | | | | | | | | | |
|---|---|---|---|---|---|---|---|---|---|
| Class (h)/ | −10 | 10 | 20 | 30 | 40 | 50 | 60 | 70 | 80 |
| temperature ° C. | | | | | | | | | |
| Comparative | 18 | 19 | 20 | 21 | 18 | 14 | 13 | 12 | 6 |
| example 1 (h) | | | | | | | | | |
| Example 1 (h) | 99 | 100 | 100 | 102 | 98 | 97 | 96 | 95 | 93 |
| Comparative | 13 | 13.5 | 14 | 14 | 12.1 | 10.1 | 8.4 | 6.5 | 3.2 |
| example 3 (h) | | | | | | | | | |
| Example 4 (h) | 118.3 | 119.5 | 120 | 119 | 117.5 | 116 | 115 | 112 | 110.4 |
| Comparative | 46.4 | 48.9 | 50 | 51 | 49.5 | 48.8 | 48 | 47.6 | 47.1 |
| example 5 (h) | | | | | | | | | |
| Example 8 (h) | 225 | 228 | 230 | 229 | 228.5 | 227.8 | 226.7 | 225.3 | 222.9 |
| Comparative | 45.6 | 48.9 | 50 | 49.7 | 46.4 | 40 | 32.4. | 24.2 | 14.1 |
| example 13 (h) | | | | | | | | | |
| Example 20 (h) | 276.3 | 283.6 | 285 | 284.6 | 283.1 | 282.1 | 280.5 | 277.9 | 276.8 |

Note:
the above test data are data of the device at 10 mA/cm².

It can be seen from in Table 6 and FIG. 9 that compared with the traditional device matching, the EQE of the device matched with the host material and the guest material used in the structure of the present application has little change at different temperatures, and the EQE of the device has almost no change at a higher temperature, indicating that the device with the present application structure matching has good device stability.

What is claimed is:

1. An organic electroluminescent device, comprising a negative electrode, a positive electrode and a luminescent layer located between the negative electrode and the positive electrode; the luminescent layer comprising a host material and a fluorescent material; a hole transport area being present between the positive electrode and the luminescent layer, and an electron transport area being present between the negative electrode and the luminescent layer; wherein,
the host material comprises a first organic compound and a second organic compound, a mixture or interface formed by the first organic compound and the second organic compound generates an exciplex under the condition of optical excitation or electric field excitation; the emission spectrum of the formed exciplex and the absorption spectrum of the fluorescent doping material are overlapped at the longest wavelength side, and the first organic compound and the second organic compound have different carrier transport characteristics;
the fluorescent material is doped into the host material, the fluorescent material is an organic compound containing boron atoms, and the longest wavelength side of the absorption spectrum of the fluorescent material and the emission spectrum of the exciplex are overlapped.

2. The organic electroluminescent device according to claim 1, wherein the first organic compound and the second organic compound form a mixture in a mass ratio of 1:99˜99:1 to generate the exciplex under the condition of optical excitation or electric field excitation.

3. The organic electroluminescent device according to claim 1, wherein the first organic compound and the second organic compound form an overlapping layer of an interface, the first organic compound is located at one side of the hole transport area, the second organic compound is located at one side of the electron transport area, and the exciplex is generated under the condition of optical excitation or electric field excitation.

4. The organic electroluminescent device according to claim 1, wherein the host material in the luminescent layer is the mixture formed by the first organic compound and the second organic compound, wherein the first organic compound is 10%˜90% by mass of the host material; the fluorescent material in the luminescent layer is 1%˜5% or 5%˜30% by mass of the host material.

5. The organic electroluminescent device according to claim 1, wherein the host material in the luminescent layer is the overlapping layer of the interface formed by the first organic compound and the second organic compound; the fluorescent material is doped into the first organic compound, and the fluorescent material in the luminescent layer is 1%˜5% or 5%˜30% by mass of the host material; or the fluorescent material is doped into the second organic compound, and the fluorescent material in the luminescent layer is 1%˜5% or 5%˜30% by mass of the host material.

6. The organic electroluminescent device according to claim 1, wherein the hole mobility of the first organic compound is greater than an electron mobility, the electron mobility of the second organic compound is greater than the hole mobility; and the first organic compound is a hole transfer type material, and the second organic compound is an electron transfer type material.

7. The organic electroluminescent device according to claim 1, wherein a difference between the highest peak wavelength of the fluorescence emission spectrum of the exciplex and the highest energy peak wavelength of the phosphorescence emission spectrum of the exciplex is less than or equal to 50 nm; the energy is transferred to a fluorescent boron-containing doping material, so that the fluorescent boron-containing material emits light.

8. The organic electroluminescent device according to claim 1, wherein a difference between the highest peak wavelength of the fluorescence emission spectrum of the fluorescent material and the highest energy peak wavelength of the phosphorescence emission spectrum of the fluorescent material is less than or equal to 50 nm.

9. The organic electroluminescent device according to claim 1, wherein the quantity of boron atoms contained in the fluorescent material is greater than or equal to 1, the boron atoms are bonded with other elements through sp2 hybrid orbits; a group connected with boron is one of a hydrogen atom, substituted or unsubstituted C1-C6 linear alkyl, substituted or unsubstituted C3-C10 cycloalkyl, substituted or unsubstituted C1-C10 heterocycloalkyl, substituted or unsubstituted C6-C60 aryl, and substituted or unsubstituted C3-C60 heteroaryl; furthermore, the groups connected with boron can be connected alone, or mutually and directly bonded to form a ring, or connected with boron after being connected with other groups to form the ring.

10. The organic electroluminescent device according to claim 1, wherein the quantity of boron atoms contained in the fluorescent material is 1, 2 or 3.

11. The organic electroluminescent device according to claim 1, wherein the guest material has a structure as shown in general formula (1): 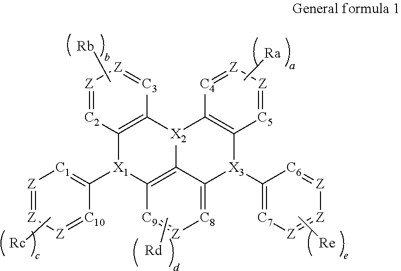
wherein, X₁, X₂ and X₃ each independently represent a nitrogen atom or a boron atom, and at least one of X₁, X₂ and X₃ is the boron atom; Z, on each occurrence, identically or differently represents N or C(R);
a, b, c, d and e each independently represent 0, 1, 2, 3, or 4; at least one pair of C₁ and C₂, C₃ and C₄, C₅ and C₆, C₇ and C₈, C₉ and C₁₀ can be connected to form a 5-7-membered ring structure;
R, on each occurrence, identically or differently represents H, D, F, Cl, Br, I, C(═O)R¹, CN, Si(R¹)₃, P(═O)(R¹)₂, S(═O)₂R¹, linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, or SO₂, and wherein one or more H atoms in the groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;
R¹, on each occurrence, identically or differently represents H, D, F, Cl, Br, I, C(═O)R², CN, Si(R²)₃, P(═O) (R²)₂, N(R²)S(═O)₂R², linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R₂C═CR²—, —C≡C—, Si(R²)₂, C(═O), C═NR², —C(═O)O—, C(═O)NR²—, NR², P(═O)(R²), —O—, —S—, or SO₂, and one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;
R², on each occurrence, identically or differently represents H, D, F or C1-C20 aliphatic, aromatic or heteroaromatic organic groups, wherein one or more H atoms can also be substituted by D or F; here, two or more substituents R² can be connected to each other and form a ring;
Ra, Rb, Rc and Rd each independently represent linear or branched C1-C20 alkyl groups, linear or branched C1-C20 alkyl substituted silyl, substituted or unsubstituted C5-C30 aryl, substituted or unsubstituted C5-C30 heteroaryl, and substituted or unsubstituted C5-C30 arylamino;
under the condition that the Ra, Rb, Rc and Rd groups are bonded with Z, the group Z is equal to C.

12. The organic electroluminescent device according to claim 1, wherein the guest material has a structure as shown in general formula (2): 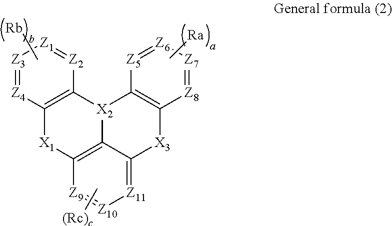
wherein, X₁ and X₃ each independently represent a single bond, B(R), N(R), C(R)₂, Si(R)₂, O, C═N(R), C═C(R)₂, P(R), P(═O)R, S or SO₂; X₂ independently represents a nitrogen atom or a boron atom, and at least one of X₁, X₂ and X₃ is the boron atom;
Z₁-Z₁₁ independently represent the nitrogen atom or C(R), respectively;
a, b, c, d and e each independently represent 0, 1, 2, 3, or 4;
R, on each occurrence, identically or differently represents H, D, F, Cl, Br, I, C(═O) R¹, CN, Si(R¹)₃, P(═O) (R¹)₂, S(═O)₂R¹, linear C1-C20 alkyl or alkoxy group, or branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, or SO₂, and wherein one or more H atoms in the groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;
R¹, on each occurrence, identically or differently represents H, D, F, Cl, Br, I, C(═O)R², CN, Si(R²)₃, P(═O) (R²)₂, N(R²)S(═O)₂R², linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R₂C═CR₂—, —C≡C—, Si(R²)₂, C(═O), C═NR², —C(═O)O—, C(═O)NR²—, NR², P(═O) (R²), —O—, —S—, or SO₂, and one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;
R², on each occurrence, identically or differently represents H, D, F or C1-C20 aliphatic, aromatic or heteroaromatic organic groups, and one or more H atoms can also be substituted by D or F; here, two or more substituents R² can be connected to each other and form a ring;
Ra, Rb, Rc and Rd each independently represent linear or branched C1-C20 alkyl groups, linear or branched C1-C20 alkyl substituted silyl, substituted or unsubstituted C5-C30 aryl, substituted or unsubstituted C5-C30 heteroaryl, and substituted or unsubstituted C5-C30 arylamino;
under the condition that the Ra, Rb, Rc and Rd groups are bonded with Z, the group Z is equal to C.

13. The organic electroluminescent device according to claim 1, wherein the guest material has a structure as shown in general formula (3): 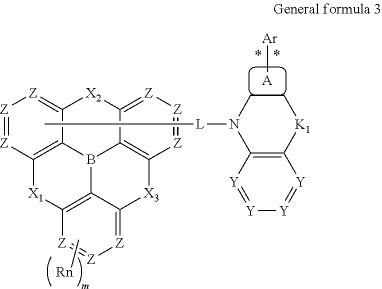
wherein, X₁, X₂ and X₃ each independently represent a single bond, B(R), N(R), C(R)₂, Si(R)₂, O, C═N(R), C═C(R)₂, P(R), P(═O)R, S or SO₂;
Z and Y at different positions independently represent C(R) or N, respectively;
K₁ represents one of a single bond, B(R), N(R), C(R)₂, Si(R)₂, O, C═N(R), C═C(R)₂, P(R), P(═O)R, S or SO₂, linear or branched C1-C20 alkyl substituted alkylene, linear or branched C1-C20 alkyl substituted silyl and C6-C20 aryl substituted alkylene; 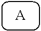
represents an aromatic group having carbon atom number of 6˜20 or a heteroaromatic group having carbon atom number of 3˜20;
m represents 0, 1, 2, 3, 4 or 5; L is selected from a single bond, a double bond, a triple bond, an aryl group having carbon atom number of 6˜40 or a heteroaromatic group having carbon atom number of 3˜40;
R, on each occurrence, identically or differently represents H, D, F, Cl, Br, I, C(═O)R¹, CN, Si(R¹)₃, P(═O)(R¹)₂, S(═O)₂R¹, linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, or SO₂, and wherein one or more H atoms in the groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring:
R¹, on each occurrence, identically or differently represents H, D, F, Cl, Br, I, C(═O)R², CN, Si(R²)₃, P(═O)(R²)₂, N(R²)S(═O)₂R², linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups of the groups can be substituted by —R₂C═CR₂—, —C≡C—, Si(R²)₂, C(═O), C═NR², —C(═O)O—, C(═O)NR²—, NR², P(═O)(R²), —O—, —S—, or SO₂, and one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;
R², on each occurrence, identically or differently represents H, D, F or C1-C20 aliphatic, aromatic or heteroaromatic organic groups, and one or more H atoms can also be substituted by D or F; here, two or more substituents R² can be connected to each other and form a ring;
Rₙ independently represents linear or branched C1-C20 alkyl substituted alkyl, linear or branched C1-C20 alkyl substituted silyl, substituted or unsubstituted C5-C30 aryl, substituted or unsubstituted C5-C30 heteroaryl, and substituted or unsubstituted C5-C30 arylamino;
Ar represents linear or branched C1-C20 alkyl substituted alkyl, linear or branched C1-C20 alkyl substituted silyl, substituted or unsubstituted C5-C30 aryl, substituted or unsubstituted C5-C30 heteroaryl, and substituted or unsubstituted C5-C30 arylamino or a structure shown in general formula (4): 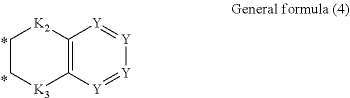
K₂ and K₃ independently represent one of a single bond, B(R), N(R), C(R)₂, Si(R)₂, O, C═N(R), C═C(R)₂, (R), P(═O)R, S or SO₂, linear or branched C1-C20 alkyl substituted alkylene, linear or branched C1-C20 alkyl substituted silyl and C6-C20 aryl substituted alkylene;
* represents ligation sites of general formula (4) and general formula (3).

14. The organic electroluminescent device according to claim 13, wherein in general formula (3), X₁, X₂ and X₃ each can also be independently absent, namely, none of atoms or bond linkages is each independently present at the positions represented by X₁, X₂ and X₃, and the atom or bond is present at the position of at least one of X₁, X₂ and X₃.

15. The organic electroluminescent device according to claim 1, wherein the hole transport area comprises one or a combination of more of a hole injection layer, a hole transport layer and an electron barrier layer; the electron transport area comprises one or a combination of more of an electron injection layer, an electron transport layer and a hole barrier layer.
